(19) United States
(12) Patent Application Publication
(10) Pub. No.: US 2026/0044655 A1
(43) Pub. Date: Feb. 12, 2026

(54) SYSTEMS, APPARATUSES, METHODS, AND COMPUTER PROGRAM PRODUCTS FOR SIMULATION AND AI-DRIVEN INTEGRATED FRAMEWORK FOR DESIGN OPTIMIZATION

(71) Applicant: Honeywell International Inc., Charlotte, NC (US)

(72) Inventors: Sunil Anthon Bardeskar, Bangalore (IN); Ivan Borastero Villan, St Germaine-en-Laye (FR); Ananda Vel Murugan Chandra Mohan, Madurai (IN)

(21) Appl. No.: 18/912,241

(22) Filed: Oct. 10, 2024

(30) Foreign Application Priority Data
Aug. 9, 2024 (IN) 202411060378

(51) Int. Cl. G06F 30/31; G06F 30/27

(52) U.S. Cl. CPC G06F 30/31; G06F 30/27

(57) ABSTRACT

Embodiments of the present disclosure relate to assembly design optimization and simulation. Optimization data may be generated for one or more assemblies using one or more machine learning models. Design simulation result prediction may be generated for the optimization data. The optimization data may be provided to one or more client computing entities in response to positive design simulation result prediction.

### CROSS-REFERENCE TO RELATED APPLICATIONS

The present application claims the benefit of India Provisional Application No. 202411060378 filed August 9, 2024, and titled “SYSTEMS, APPARATUSES, METHODS, AND COMPUTER PROGRAM PRODUCTS FOR SIMULATION AND AI-DRIVEN INTEGRATED FRAMEWORK FOR OPTIMIZATION OF PCBA AND ELECTRONIC COMPONENTS AT SCALE,” which is hereby incorporated by reference in its entirety

### TECHNICAL FIELD

The present disclosure relates, generally, to assembly design and redesign. Example embodiments provide systems, apparatuses, methods, and computer program products for simulation and AI-driven integrated framework for design optimization such as printed circuit board design optimization and printed wiring board design optimization.

### BACKGROUND

Applicant has discovered problems associated with current implementations of assembly design and/or redesign. Through applied effort, ingenuity, and innovation, Applicant has solved many of these identified problems by developing solutions embodied in the present disclosure, which are described in detail below.

### BRIEF SUMMARY

Example embodiments provide systems, apparatuses, methods, and computer program products for simulation and AI-driven integrated framework for design optimization.

In accordance with one aspect of the present disclosure, a computer-implemented method for assembly optimization and simulation is provided. The computer-implemented method is executable using any of a myriad of computing device(s) and/or combinations of hardware, software, and/or firmware. In some example embodiments, an example computer-implemented method includes identifying, by one or more processors, one or more assemblies, wherein each assembly of the one or more assemblies comprises a plurality of components; generating, by the one or more processors, optimization data for the one or more assemblies based on input data associated with the one or more assemblies and using one or more machine learning models, wherein the optimization data comprises recommended component list data for each of the one or more assemblies; generating, by the one or more processors, design simulation result prediction for the optimization data for the one or more assemblies; and providing, by the one or more processors, the optimization data to one or more client computing entities in response to a positive design simulation result prediction.

In some embodiments, the input data comprises at least initial component list data for each of the one or more assemblies.

In some embodiments, the example computer-implemented method further includes generating design simulation result based on the optimization data for at least one of the one or more assemblies by performing one or more design simulations with respect to the optimization data.

In some embodiments, the example computer-implemented method further includes providing the design simulation result as feedback to the one or more machine learning models, wherein the one or more machine learning models are configured to learn patterns of changes to assemblies that pass or fail the one or more design simulations.

In some embodiments, the one or more design simulations comprises one or more of signal integrity simulation, power integrity simulation, thermal analysis, or reliability analysis.

In some embodiments, the one or more machine learning models comprise a large language model.

In some embodiments, generating the optimization data further comprises performing one or more of component replacement-based optimization, component standardization-based optimization, or functional block-based optimization.

In some embodiments, the one or more assemblies comprise a plurality of assemblies, and performing the functional block-based optimization comprises identifying a plurality of functional blocks associated with the plurality of assemblies based on (i) a schematic for each of the plurality of assemblies, (ii) specification for one or more operating parameters for each of the plurality of assemblies, and (iii) initial component list data for each of the plurality of assemblies; generating one or more functional block groups based on data associated with the plurality of functional blocks and using a clustering machine learning model, wherein each functional block groups comprises one or more functional blocks from the plurality of functional blocks having similar characteristics; and generating a standard functional block for each functional block group of the one or more functional block groups.

In accordance with another aspect of the present disclosure, an apparatus for assembly optimization and simulation is provided. The apparatus in some embodiments includes at least one processor and at least one non-transitory memory, the at least one non-transitory memory having computer-coded instructions stored thereon. The computer-coded instructions in execution with the at least one processor causes the apparatus to perform any of the example computer-implemented methods described herein. In some other embodiments, the apparatus includes means for performing each step of any of the computer-implemented methods described herein.

In accordance with another aspect of the present disclosure, a computer program product for assembly optimization and simulation is provided. The computer program product in some embodiments includes at least one non-transitory computer-readable storage medium having computer program code stored thereon. The computer program code in execution with at least one processor is configured for performing any one or the example computer-implemented methods described herein.

### BREIF DESCRIPTION OF THE SEVERAL VIEWS OF THE DRAWINGS

Having thus described the embodiments of the disclosure in general terms, reference now will be made to the accompanying drawings, which are not necessarily drawn to scale, and wherein:

FIG. 1 illustrates a block diagram of an example system architecture in which embodiments of the present disclosure may operate.

FIG. 2 illustrates a block diagram of an example apparatus in accordance with at least one example embodiment of the present disclosure.

FIG. 3a illustrates example visualization of data structures, modules, and processes for end-to-end assembly optimization and simulation in accordance with at least one example embodiment of the present disclosure.

FIG. 3b illustrates example visualization of data structures, modules, and processes for generating assembly schematic in accordance with at least one example embodiment of the present disclosure.

FIGS. 3c-3d illustrate example visualization of data structures, modules, and processes for component replacement-based optimization in accordance with at least one example embodiment of the present disclosure.

FIG. 3e illustrate example visualization of data structures, modules, and processes for functional block-based optimization in accordance with at least one example embodiment of the present disclosure.

FIG. 3f illustrates example visualization of data structures, modules, and processes for component standardization-based optimization in accordance with at least one example embodiment of the present disclosure.

FIG. 4 illustrates a flowchart for simulation and AI-driven integrated framework for design optimization in accordance with at least one example embodiment of the present disclosure.

### DETAILED DESCRIPTION

Various embodiments of the present disclosure now will be described more fully hereinafter with reference to the accompanying drawings, in which some, but not all, embodiments of the present disclosure are shown. Indeed, the present disclosure may be embodied in many different forms and should not be construed as limited to the embodiments set forth herein, rather, these embodiments are provided so that this disclosure will satisfy applicable legal requirements.

The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not indicate being based only on or based solely on the referenced element or elements unless so indicated. Like numbers refer to like elements throughout.

### OVERVIEW AND TECHNICAL IMPROVEMENTS

Various embodiments of the present disclosure are generally directed to systems, apparatuses, methods, and computer program products for simulation and AI-driven integrated framework for design optimization.

Existing methods of value engineering and component engineering (VECE), particularly with respect to assemblies such as printed circuit board assemblies and printed wired board assemblies, face various challenges including, but not limited to, low efficiency and high resource usage. Embodiments of the present disclosure, using artificial intelligence/machine learning (AI/ML), provides for efficient analysis and optimization of assemblies and related assets including such assembly.

Example embodiments, using one or more machine learning models, perform end-to-end optimization and analysis of assemblies that identifies assemblies for optimization, identifies components (e.g., electronic components) in an assembly associated with one or more issues, and generates optimization data that includes replacement recommendations for such components. Example embodiments, identify functional blocks across multiple assemblies based on corresponding schematics and generates optimization data that includes functional block standardization recommendations across the multiple assemblies and/or related assets. Example embodiments analyze components of assemblies and generate optimization data that includes recommendations for reducing component variants, and recommendations for modularizing components. In this regard, example embodiments generate optimization data that improve space utilization in assemblies; reduce size and/or weight of assemblies; reduce impact value of components and assemblies such as, for example, cost; reduce risk such as, for example, safety risk and/or obsolescence risk, improve design efficiency, reduce resource consumption, and improve overall assembly performance, to name a few. Further, example embodiments validate optimization recommendations using one or more simulation techniques and/or machine learning models.

Example embodiments implement an adaptive learning framework and/or technique, where the machine learning models configured to generate optimization data are further configured to predict the outcome of one or more design simulations for the generated optimization data. The one or more machine learning models may be configured to learn updates (e.g., modifications) to an assembly design that would pass or fail the corresponding design simulation when such design simulations are performed on the updated assembly that includes such updates. Example embodiments include a feedback mechanism to provide the result of design simulations to the machine learning models such that the machine learning models learn the patterns of assembly changes/modifications that pass or fail the design simulation(s) (e.g., without explicitly running the simulations).

By using adaptive learning techniques to predict the outcome of a design simulations and providing feedback to the machine learning models configured to generate optimization data for assemblies, example embodiments improve the accuracy of such machine learning models and optimization systems, which otherwise may not be achievable or feasible. For example, it may be impractical to run/execute the multiple simulations needed for each assembly. Further, by learning the pattern of assembly modifications that pass or fail a design simulation and predicting the outcome of design simulation for generated optimization data based on the learned pattern, at least some embodiments of the present disclosure may reduce the number of design simulations needed for validation or obviate the need to perform such design simulations, which in turn increases efficiencies, reduces resource usage, and reduces latency with respect to optimization and implementation of assembly redesign.

Moreover, existing solutions are generally manual processes that are less structured and result in slow, inefficient and inaccurate value engineering and component engineering (VECE) ideas and not cable of batch optimization of assemblies, which limits the ability to identify impact value optimization opportunities that could be found by analyzing multiple assemblies simultaneously. Example embodiments solve these challenges at least in part by using AI/ML and simulation with automated sequence of actions to generate and validate assembly design optimization opportunities (e.g., impact value optimization, risk optimization, performance optimization, and/or the like) and perform these analysis at scale by processing a plurality of assemblies together (e.g., batch).

In this regard, embodiments of the present disclosure provide various technical advantages and improves various technical fields including, but not limited to, the technical field of assembly design and the technical field of value engineering and component engineering.

### DEFINITIONS

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

As used herein, the terms “data,” “content,” “digital content,” “information,” and similar terms may be used interchangeably to refer to data capable of being transmitted, received, and/or stored in accordance with embodiments of the present disclosure. Further, where a computing entity is described herein to receive data from another computing entity, it will be appreciated that the data may be received directly from another computing entity or may be received indirectly via one or more intermediary computing entities, such as, for example, one or more servers, relays, routers, network access points, base stations, hosts, and/or the like, sometimes referred to herein as a “network.” Similarly, where a computing entity is described herein to send data to another computing device, it will be appreciated that the data may be sent directly to another computing entity or may be sent indirectly via one or more intermediary computing devices, such as, for example, one or more servers, relays, routers, network access points, base stations, hosts, and/or the like.

In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entities may be operated by various parties.

In some embodiments, a computing entity may be embodied as an artificial intelligence (AI) computing entity. Accordingly, the computing entity may be configured to provide and/or receive information/data from a user via an input/output mechanism, such as a display, a camera, a speaker, a voice-activated input, and/or the like. In certain embodiments, an AI computing entity may comprise one or more predefined and executable program algorithms stored within an onboard memory storage module, and/or accessible over a network. In some embodiments, the AI computing entity may be configured to retrieve and/or execute one or more of the predefined program algorithms upon the occurrence of a predefined trigger event.

The term “assembly” and “assemblies” as used herein refer to any item that includes components configured to, individually and/or collectively, perform a particular function(s). Such components may include electronic components, mechanical components, and/or the like. For example, an assembly may include one or more electronic components (e.g., resistors, capacitors, and/or the like). Alternatively or additionally, an assembly may include one or more mechanical components. In some embodiments, an assembly includes one or more components disposed and/or formed on and/or in a substrate. In particular, in some embodiments, examples of an assembly include printed circuity board assembly (assembly), printed wiring board assembly (PWBA), and/or the like. In some embodiments, the substrate (e.g., PCB, PWB, or the like) of an assembly may comprise a component of the assembly.

The term “printed circuit board” and “PCB” refers to a substrate that includes insulating material and/or conductive material.

The term “printed circuit board assembly” and “assembly” refers to a PCB having one or more components disposed thereon and/or therein. An assembly, for example, may describe a PCB with components assembled therein.

The term “printed wiring board” and “PWB” refers to a substrate that includes insulating material and/or conductive material.

The term “printed wiring board assembly” and “PWBA” refers to a PWB having one or more components disposed thereon and/or therein. A PWBA, for example, may describe a PWB with components assembled thereon and/or therein.

The term “schematic” refers to a representation of an assembly that illustrates the connections between components of the assembly. For example, a schematic may comprise a technical drawing, a diagram, and/or the like that shows electrical connections and functions of a specific circuit arrangement using graphic symbols.

The term “trace” refers to a path (e.g., copper path printed on a substrate configured for connecting components in an assembly (e.g.., components disposed on an assembly).

The term “component” may refer to an item that is placed on an a substate such as a PCB or PWB. Non-limiting examples of a component include resistors, capacitors, connectors, integrated circuits, and/or the like.

The term “PCB layout” and “assembly layout” refer to a physical representation of a PCB or assembly.

The term “netlist” refers to electrical connections in an assembly represented in a human-readable format.

The term “value engineering and component engineering” refers to a product design and/or development methodology configured to optimize as asset (e.g., a product, item, or other similar terms). Value engineering and component engineering (VECE) leverages various engineering and analytical techniques to select components of an asset that optimizes the asset and/or asset development, including product improvement. VECE may include analyzing and redesigning workflows and procedures to, for example, reduce manufacturing challenges, including manufacturing impact values, improving manufacturing speed, streamlining product manufacturing to make assets easier to manufacture.

### EXAMPLE SYSTEMS AND APPARATUSES OF THE DISCLOSURE

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established, or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

A non-volatile computer-readable storage medium may include a floppy disk, flexible disk, hard disk, solid-state storage (SSS) (e.g., a solid-state drive (SSD), solid-state card (SSC), solid-state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

A volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

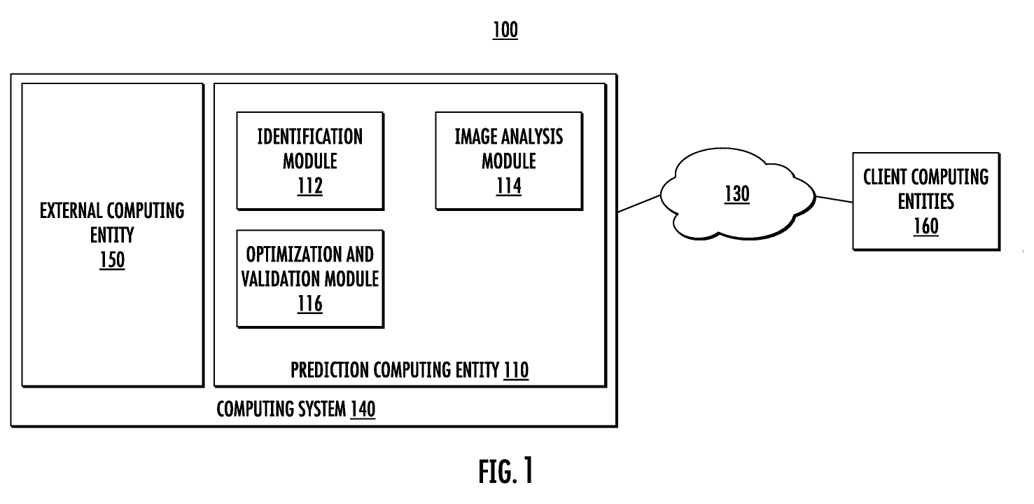

In this regard, FIG. 1 provides an example overview of a system architecture 100 in accordance with at least some example embodiments of the present disclosure. The depiction of the example architecture 100 is not intended to limit or otherwise confine the embodiments described and contemplated herein to any particular configuration of elements or systems, nor is it intended to exclude any alternative configurations or systems for the set of configurations and systems that can be used in connection with embodiments of the present disclosure. Rather, FIG. 1 and the architecture 100 disclosed therein is merely presented to provide an example basis and context for the facilitation of some of the features, aspects, and uses of the methods, apparatuses, computer readable media, and computer program products disclosed and contemplated herein. It will be understood that while many of the aspects and components presented in FIG.1 are shown as discrete, separate elements, other configurations may be used in connection with the methods, apparatuses, computer readable media, and computer programs described herein, including configurations that combine, omit, separate, and/or add aspects and/or components. The example system architecture 100 may be used in a plurality of domains and not limited to any specific application as disclosed herewith. In particular, while some example embodiments are described herein with reference to a particular domain, the example system architecture 100 may be used in a plurality of domains and not limited to any specific application as disclosed herein. The plurality of domains may include healthcare, industrial, manufacturing, education, retail, to name a few.

As illustrated, the system architecture 100 includes a computing system 140 (e.g., assembly design optimization system 140) configured to receive requests from client computing entities 160, process the requests to generate predictive outputs, and provide the predictive output to the client computing entities 160. In various embodiments, such predictive outputs may include optimization data for an assembly or group of assemblies. The example architecture 100 may be used in a plurality of domains and not limited to any specific application as disclosed herewith.

In some embodiments, the computing system 140 may communicate with at least one of the client computing entities 160 using one or more communication networks, for example a communications network 130.

It should be appreciated that the communications network 130 in some embodiments is embodied in any of a myriad of network configurations. In some embodiments, the communications network 130 embodies a public network (e.g., the Internet). In some embodiments, the communications network 130 embodies a private network (e.g., an internal localized, or closed-off network between particular devices). In some other embodiments, the communications network 130 embodies a hybrid network (e.g., a network enabling internal communications between particular connected devices and external communications with other devices). The communications network 130 in some embodiments includes one or more base station(s), relay(s), router(s), switch(es), cell tower(s), communications cable(s) and/or associated routing station(s), and/or the like. In some embodiments, the communications network 130 includes one or more user-controlled computing device(s) (e.g., a user owned router and/or modem) and/or one or more external utility devices (e.g., Internet service provider communication tower(s) and/or other device(s)).

Each of the components of the system architecture 100 may be communicatively coupled to transmit data to and/or receive data from one another over the same or different wireless and/or wired networks embodying the communications network 130. Such configuration(s) include, without limitation, a wired or wireless Personal Area Network (PAN), Local Area Network (LAN), Metropolitan Area Network (MAN), Wide Area Network (WAN), and/or the like. Additionally, while FIG. 1 illustrate certain system entities as separate, standalone entities communicating over the communications network 130, the various embodiments are not limited to this architecture. In other embodiments, one or more computing entities share one or more components, hardware, and/or the like, or otherwise are embodied by a single computing device such that connection(s) between the computing entities are over the communications network 130 are altered and/or rendered unnecessary.

In various embodiments, the computing system 140 is configured to optimize assembly designs in accordance with one or more optimization techniques of the present disclosure. Additionally, in various embodiments, the computing system 140 is configured to validate optimization data generated via the one or more optimization techniques. The computing system 140, for example, may be configured to implement and execute an end-to-end integrated AI and simulation framework for assembly design optimization and validation that takes electronic computer aided design and/or image of one or more assemblies along with component list data and/or asset data (e.g., including asset specification data) as input, generates, using or more artificial intelligence/machine learning (AI/ML) models, predictive output comprising optimization data, and validates the optimization data. In various embodiments, the predictive output comprises optimization data for an assembly or group of assemblies. In some embodiments, optimization data comprise one or more items of data representative and/or indicative of one or more recommendations for improving design of an assembly or group of assemblies. In some embodiments, the predictive output may, additionally, include analysis data for the assembly or group of assemblies. Alternatively or additionally, in some embodiments, the predictive output may be augmented to include the validation data.

The computing system 140 may include a predictive computing entity 110 configured to receive requests from client computing entities 160, process the requests to generate predictive outputs, and provide the predictive output to the client computing entities 160, such as analysis data and/or optimization data for an assembly or group of assemblies.

In various the computing system 140 is configured to apply the predictive output to the assembly or group of assemblies to modify design of an assembly or group of assemblies. For example, the computing system 140 may be configured to transmit instructions to one or more systems, computing entities, and/or the like, wherein the instructions are configured to cause modification to the configuration and/or design of one or more assemblies based on the optimization data and/or analysis data. In particular, in some embodiments, the computing system 140 is configured to perform one or more prediction-based actions, including one or more optimized design implementation actions. Such optimized design implementation actions may include transmitting instructions configured to cause redesign of an assembly or group of assemblies, as described herein.

In various embodiments, the predictive computing entity 110 includes an identification module 112, an image analysis module 114, and/or an optimization and validation module 116. The identification module 112, image analysis module 114, and/or optimization and validation module 116 may be individually and/or collectively configured for performing various operations associated with the predictive computing entity 110, including assembly design optimization and validation according to techniques described herein to generate a predictive output. Each of the identification module 112, image analysis module 114, and/or optimization and validation module 116 may be or otherwise comprise hardware, software, firmware, and/or a combination thereof, configured to perform functionalities associated with the respective module, including one or more operations associated with assembly design optimization and validation.

In various embodiments, the predictive computing entity 110 (e.g., one or more of the identification module 112, image analysis module 114, and/or optimization and validation module 116) leverages one or more machine learning models (e.g., including artificial intelligence and/or machine learning) to perform and/or facilitate performance of one or more operations associated with assembly design optimization and validation according to one or more techniques described herein. For example, one or more of the identification module 112, image analysis module 114, and/or optimization and validation module 116 may include or is otherwise associated with one or more machine learning models configured to perform and/or facilitate performance of one or more operations associated with assembly design optimization and validation as described herein. Such operations may include predictive data analysis, image analysis, image recognition, image enhancement, optimization, and/or other operations according to techniques described herein. The predictive computing entity 110 may be configured to train, implement, use, and/or update the one or more machine learning models or a portion thereof. In some embodiments, the one or more machine learning models collectively define a composite design optimization machine learning model, where each of the one or more machine learning models may represent a component of the composite design optimization machine learning model and configured to support performance of one or more stages of an assembly design optimization and/or validation process, as described herein. In some embodiments, the composite design optimization machine learning model may include only a portion of the one or more machine learning models leveraged by the predictive computing entity 110 to perform assembly design optimization, as described herein.

The predictive computing entity 110 may comprise a storage subsystem that may be configured to store input data, training data, and/or the like that may be used by the predictive computing entity 110 (e.g., one or more of the identification module 112, image analysis module 114, and/or optimization and validation module 116 thereof) to perform predictive data analysis, image analysis, optimization, and/or training operations of the present disclosure. In addition, the storage subsystems may be configured to store model definition data used by the predictive computing entity 110 to perform various predictive data analysis and/or training operations.

The storage subsystem may include one or more storage units, such as multiple distributed storage units that are connected through a computer network. Each storage unit in the respective computing entities may store at least one of one or more data assets and/or one or more data about the computed properties of one or more data assets. Moreover, each storage unit in the storage systems may include one or more non-volatile storage or memory media including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

In some embodiments, the predictive computing entity 110 may be communicatively coupled to or more external computing entities 150 (e.g., using one or more wired and/or wireless communication techniques). In some embodiments, the external computing entities 150 may be specially configured to perform one or more steps/operations of one or more techniques described herein. In some examples, the external computing entities may be configured to train, implement, use, and/or update machine learning models in accordance with one or more techniques of the present disclosure. The one or more external computing entities 150 may include storage subsystems, such as storage subsystem described above with respect to the predictive computing entity 110.

In some embodiments, the identification module 112 is configured to identify a target assembly for optimization from an aggregated dataset associated with one or more assets and based on selection criteria. In some embodiments, the identification module 112 is configured to access, receive, and/or generate the aggregated dataset via one or more data sources. The one or more data sources may store data such as asset lifecycle management data (PLM data), enterprise resource planning (ERP) data, and/or other data associated with assemblies used in at least one of the one or more assets.

In some embodiments, the selection criteria includes assembly impact value (e.g., impact value of an assembly such as, for example, cost, resource usage, and/or the like associated with the assembly), related asset impact value (e.g., impact value for an asset that includes the assembly such as, for example, cost, resource usage, and/or the like associated with the related asset), assembly risk level (e.g., risk level associated with an assembly such as, for example, safety risk, end of life risk, and/or the like), assembly performance (e.g., performance of an assembly with respect to one or more key performance indicators (KPIs)), assembly physical characteristics (e.g., weight, dimension, and/or the like of an assembly), assembly usage (e.g., actual and/or predicted demand for an assembly based on, for example, sales, inventory and operations planning (SIOP)), assembly predicted end of life (e.g., predicted end of life for an assembly) related asset end of life ( predicted end of life for an asset that includes the assembly), predicted end of life for assembly component(s), and/or the like), component list data such as, for example, bill of materials (BOM) associated with an assembly or related asset.

In various embodiments, the aggregated dataset comprises data regarding the selection criteria for each of one or more assemblies. The identification module 112 may be configured to analyze, for each of one or more assemblies (or one or more components thereof), at least a portion of the aggregated dataset comprising data for the assembly and identify one or more assemblies for optimization (referred to herein as target assembly). In some embodiments, the identification module 112 leverages one or more machine learning models to identify the one or more target assemblies. The one or more machine learning models may be trained, configured, and/or the like to receive aggregated dataset, analyze the aggregated dataset based on the selection criteria, and output data that describes one or more target assemblies such as, for example, assembly identifiers. In some embodiments, the selection criteria is configurable.

The one or more machine learning models may comprise a component of the composite design optimization machine learning model. In some embodiments, the one or more machine learning models may comprise an analytical machine learning model. In some embodiments, the analytical machine learning model is a data entity that describes parameters, hyper-parameters, and/or defined operations of a rules-based algorithm, machine learning model (e.g., model including at least one or more rule-based layers, one or more layers that depend on trained parameters, coefficients, and/or the like), and/or artificial intelligence model, and/or the like. An analytical machine learning model may include any type of model configured, trained, and/or the like to perform predictive analysis task on a dataset, such aggregated dataset described below, to identify an assembly (or group of assemblies) from a plurality of assemblies as a target assembly (or group of assemblies) for design optimization. In this regard, an analytical machine learning model may be configured to utilize one or more of any types of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the analytical machine learning model is a component of a composite design optimization machine learning model, as described above.

In some embodiments, an assembly may be identified as a target assembly based on one or more issues diagnosed as being associated with the assembly. Non-limiting examples of such issues include assembly faults (e.g., performance faults and/or defects), risk factors (e.g., safety risk, obsolescence risk, availability risk, end of life risk, and/or the like), above predetermined thresholds, impact value above predetermined threshold, performance data (e.g., KPIs) below predetermined thresholds. The computing system 140 may be configured to diagnose such issue(s) that may be associated with an assembly based on the aggregated dataset and/or by performing diagnostic operation on the assembly. The predictive computing entity 110, for example, may include a diagnosis module configured to analyze assemblies and/or perform diagnostic operations on assemblies to diagnose issues associated with the assemblies. The diagnosis module may comprise hardware, software, firmware, and/or a combination thereof, configured to perform such functionalities. In some embodiments, the diagnosis module may be configured to electronically connect to an assembly to diagnose faults (e.g., performance faults and/or defects) associated with an assembly and/or one or more components thereof. Alternatively or additionally, in some embodiments, the identification module 112 may be configured to diagnose issues that may be associated with assemblies.

In some embodiments, the identification module 112 is configured to cause rendering of a user interface on a client computing entity. The identification module 112 may receive user input via the user interface. The user interface may comprise one or more interface elements, including one or more filtering interface elements for configuring the selection criteria leveraged to identify target assemblies for optimization. For example, the identification module 112 may provide a user interface to create configurable filtering methodology for selecting target assemblies for optimization based on dynamic priorities and policies.

In some embodiments, the image analysis module 114 is configured for generating schematics for target assemblies using one or more machine learning models and based on image(s) of the target assemblies. In some embodiments, the image analysis module 114 may be configured to analyze and generate schematics for assemblies without an electronic computer-aided design (ECAD).

The image analysis module 114 may be configured to input an assembly image (e.g., image of target assembly) to one or more models configured to act on the image and/or data or other image derived from the image to generate a schematic for the assembly.

In some embodiments, the one or more machine learning models comprise an image recognition and analysis model such as a computer vision model configured to receive an assembly image as input and analyze/process the assembly image to detect and identify components in the assembly image and connections (e.g., electrical connections) between the detected components (e.g., corresponding to the components and connections in the assembly), and output data that describes the detected components and connections. The output of the image recognition and analysis model may comprise identifying data for the detected components that describes the component type (e.g., part number such as manufacturer part number, reference designators, and/or other identifying data), component region data that describes component regions in the target assembly, and/or enhanced assembly image of at least a portion of the target assembly. The image recognition and analysis model may be configured to generate an enhanced assembly image of the target assembly based on the input assembly image such that visual representations of the connections between the detected components are enhanced and may be analyzed to generate an assembly schematic (e.g., schematic of the assembly) based at least in part on the enhanced assembly image.

In some embodiments, the image recognition and analysis model is a data entity that describes parameters, hyper-parameters, and/or defined operations of a rules-based algorithm and/or machine learning model (e.g., model including at least one or more rule-based layers, one or more layers that depend on trained parameters, coefficients, and/or the like), and/or artificial intelligence model, and/or the like. An image recognition and analysis model may include any type of model configured, trained, and/or the like to identify components of an assembly. Alternatively or additionally, an image recognition and analysis model may include any type of model configured, trained, and/or the like to generate enhanced images of an assembly. In this regard, an image recognition and analysis model may be configured to utilize one or more of any types of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the image recognition and analysis model is a component of a composite design optimization machine learning model, described above.

In some embodiments, the image recognition and analysis model may be configured to generate an assembly schematic based on the enhanced assembly image, identifying data for the detected components, identified component regions, and/or other input such as specification data for the detected components, assembly design guidelines and/or electrical laws and engineering guidelines. A non-limiting example of an assembly design guideline is a PCBA design guideline.

In some embodiments, the one or more machine learning models comprise a multi-modal large language model configured to receive input comprising enhanced assembly image, identifying data for detected components, identified component regions, specification data for the detected components, specification data for related asset(s), assembly design guidelines and/or electrical laws and engineering guidelines. The multi-modal large language model may be configured to analyze input to the multi-modal large language model and generate an assembly schematic (e.g., schematic for an assembly) in accordance with the assembly design guidelines and/or electrical laws and engineering guidelines.

In some embodiments, the image analysis module 114 is configured to obtain specification data associated with detected components and/or related asset (e.g., component specification data, asset specification data). Such specification data may comprise specification (e.g., a value, range, and/or the like) for each of one or more operating parameters and/or other characteristics of the respective component and/or respective asset.

In some embodiments, the optimization and validation module 116 is configured to optimize assemblies (or portion of an assembly) based on input data associated with the assembly (or portion of the assembly). For example, the optimization and validation module 116 may be configured to optimize a target assembly based on input data associated with the target assembly. In some embodiments, the input data comprises the schematic for the assembly (e.g., generated by the image analysis module 114, component list data associated with the assembly, electrical connection data for the assembly, specification data for the assembly, specification data for components of the assembly, specification data for related asset(s), and/or other relevant data associated with the assembly or related asset.

The optimization and validation module 116 may be configured to optimize an assembly or group of assemblies according to one or more optimization operations and/or techniques of the present disclosure such as, but not limited to, component replacement-based optimization, functional block-based optimization, component-standardization-based optimization, and/or modularization-based optimization.

In some embodiments, optimizing an assembly comprises performing component replacement-based optimization as described herein. Component replacement-based optimization may comprise identifying one or more components of a target assembly as a target component for replacement based on one or more issues diagnosed as being associated with the respective components. Non-limiting examples of such issues include component faults (e.g., performance faults and/or defects), risk factors (e.g., safety risk, obsolescence risk, availability risk, end of life risk, and/or the like), above predetermined thresholds, impact value above predetermined threshold, performance data (e.g., KPIs) below predetermined thresholds. The computing system 140 may be configured to diagnose such issue(s) that may be associated with a component based on the aggregated dataset, data associated with the component (e.g., impact value, risk, end of life, and/or the like), and/or by performing diagnostic operation on the component. As described, above, in some embodiments, the predictive computing entity 110 may include a diagnosis module configured to analyze assemblies and/or components and/or perform diagnostics on components to diagnose issues that may be associated with the components. Alternatively or additionally, in some embodiments, the identification module 112 may be configured to diagnose such issues that may be associated with assemblies and/or components.

Alternatively or additionally, component replacement-based optimization may comprise identifying optimal replacement components for replacing identified component(s)/target component(s) based one or more optimization parameters and/or optimization constraints. Non-limiting examples of such optimization parameters include assembly physical characteristics (e.g., dimensions, weight, and/or the like), assembly impact value, assembly performance, safety risk, obsolescence risk, and/or or end of life risk. Alternatively or additionally, component replacement-based optimization may comprise redesigning a target assembly to include identified replacement component(s). Non-limiting examples of such optimization constraints include specification data for one or more operating parameters associated with related assets (e.g., an asset that includes the target assembly) comprising the target component(s), specification data for one or more operating parameters for the target component(s) and/or specification data for one or more other components electrically connected to the target component(s), dimension and/or weight of the substrate, such as electronic board, for the assembly, and/or the like.

In some embodiments, the optimization and validation module 116 is configured to input component list data associated with a target assembly and/or a schematic of the target assembly to a machine learning model configured to analyze the input data (e.g., component list data and/or assembly schematic) and generate optimization data that includes one or more recommended component list data for the target assembly. In some embodiments, the optimization and validation module 116 is configured to input component list data associated with each of a plurality of target assemblies and/or a schematic of each of the target assembly to a machine learning model configured to analyze the input data (e.g., component list data and/or assembly schematic for each of the plurality of assemblies) and generate one or more recommended component list data for each of the one or more target assemblies. In some embodiments, a recommended component list data comprises one or more recommended replacement components for at least one component of a target assembly identified as a target component based on diagnosed issue(s) associated with the respective component. A recommended component list data may represent optimal component list data for an assembly that maximizes the one or more optimization parameter (as described above) or portion thereof while taking into account the one or more optimization constraints (as described above).

In some embodiments, the optimization and validation module 116 is configured to identify a related asset associated with a target assembly by analyzing, using one or more machine learning models, component list data (e.g., current component list data) associated with the target assembly. In some embodiments, a related asset is an item that includes one or more assemblies as component thereof. For example, an item may include a printed circuit board assembly, printed wiring board assembly, and/or other assembly types as a component thereof. An item may be an electrical item, a mechanical item, an electromechanical item, a resin item, and/or the like. Examples of an item include a sensor, a bar code scanner, and/or the like.

In some embodiments, the optimization and validation module 116 is configured to identify candidate replacement component(s) for replacing a target component. In some embodiments, the candidate replacement component(s) are identified based on component type, component function, and/or component features. For example, in some embodiments, one of one or more criteria for a component to qualify as a candidate replacement may comprise that the component be of the same component type as the target component and/or perform the same function(s) as the target component.

Alternatively or additionally, in some embodiments, the candidate replacement component(s) are identified based on impact cost associated with each candidate replacement component, safety risk associated with each candidate replacement component, obsolescence risk associated with each candidate replacement component, and/or one or more other optimization parameters, as described above. By way of example, a component may be identified as a candidate replacement component for replacing one or more components of an assembly based on the candidate replacement component having an impact value that satisfies an impact value threshold (e.g., below a predetermined impact value threshold). As another example, a component may be identified as a candidate replacement component for replacing one or more components of an assembly based on the candidate replacement component having a predicted end of life that satisfies an end of life threshold (e.g., above a predetermined end of life threshold). As yet another example, a component may be identified as a candidate replacement component for replacing one or more components of an assembly based on the candidate replacement component having a predicted performance that satisfies a performance threshold (e.g., above a predetermined performance threshold). In some embodiments, one or more machine learning models may be leveraged to identify candidate replacement components based on the criteria described above and data associated with a component being evaluated to determine if the component qualifies as a candidate replacement component. The one or more machine learning models may comprise a component of the composite design optimization machine learning model.

In some embodiments, the optimization and validation module 116 is configured to generate comparison data for a candidate replacement component based on the specification data for the candidate replacement component and the specification data for the target component. The comparison data may comprise data that describes similarities and/or differences between the candidate replacement component and target component. Alternatively or additionally, the comparison data may comprise the specification data for the candidate replacement component and the target component. The optimization and validation module 116 may be configured to select one or more replacement components from the candidate replacement components based on the comparison data and specification data for one or more related assets by correlating the comparison data for a candidate replacement component with specification data for a respective related asset.

The optimization and validation module 116 may be configured select candidate replacement component as a recommended replacement component for a target component based at least in part on technical similarities between the replacement component and the target component, candidate replacement component inventory and/or target component inventory (e.g., available inventory for the candidate replacement component and/or target component), predicted future demand for the candidate replacement component and/or target component. The optimization and validation module 116 may leverage an optimization machine learning model comprising an optimization algorithm configured to optimize an objective function that comprises one or more optimization parameters (e.g., impact value, risk, performance, and/or the like) and one or more optimization constraints (e.g., specification for one or more operation parameters and/or other characteristics for the target component, target assembly associated with the target component, and/or related asset) to select optimal replacement components.

In some embodiments, the optimization machine learning model is a data entity that describes parameters, hyper-parameters, and/or defined operations of a rules-based algorithm and/or machine learning model (e.g., model including at least one or more rule-based layers, one or more layers that depend on trained parameters, coefficients, and/or the like), and/or artificial intelligence model, and/or the like. An optimization machine learning model may include any type of model configured, trained, and/or the like to generate optimization data for an assembly or group of assemblies. In this regard, an optimization machine learning model may be configured to utilize one or more of any types of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the optimization machine learning model is a component of a composite design optimization machine learning model, as described herein.

The optimization and validation module 116 may be configured to output optimization data comprising component identifiers for the selected one or more replacement components and/or other data associated with the selected one or more replacement components. For example, the optimization data may comprise one or more items of data that describes the selected one or more replacement components.

In some embodiments, the optimization and validation module 116 may be configured to generate (e.g., using one or more machine learning models) additional recommendations based on available excess inventory and/or future demand.

Alternatively or additionally, in some embodiments, optimizing an assembly comprises performing functional block-based optimization as described herein. In some embodiments, functional block-based optimization comprises standardizing functional blocks associated with a plurality of assemblies. In some embodiments, a functional block in an assembly is a self-contained module or sub-circuit in an assembly designed to perform a specific function. Non-limiting examples of functional blocks include power supply modules, controllers, circuit protection, and/or the like. The optimization and validation module 116 may be configured to optimize, using one or more machine learning models, multiple assemblies by performing functional block analysis across the multiple assemblies.

In some embodiments, the optimization and validation module 116 is configured to, using one or more machine learning models, analyze assembly schematics, component list data, electrical connection data (e.g., netlist, or the like), and/or other relevant data associated with a plurality of assemblies to identify functional blocks associated with each assembly.

In some embodiments, the optimization and validation module 116 may be configured to group the functional blocks into one or more functional block groups. In some embodiments, the optimization and validation module 116 may be configured to generate clustering data comprising data that describes and/or reflects similarities among the functional blocks (or a portion thereof) and group the functional blocks based on the clustering data. For example, the optimization and validation module 116, using one or more clustering techniques, may group the plurality of functional blocks into one or more groups (e.g., referred to herein as functional block groups) based on the clustering data. In some embodiments, the clustering data may comprise similarity scores or other representations of a similarity measure. For example, the optimization and validation module 116 may be configured to group the functional blocks into functional block groups based on Euclidean distance measure-based similarity, cosine similarity measure, and/or other similarity measures. The optimization model, for example, using a clustering machine learning model, may be configured to apply a similarity measure algorithm to the functional blocks to group the functional blocks into functional block groups based on distance measure similarity, cosine similarity, and/or the like.

The optimization and validation module 116 may be configured to generate one or more standard functional blocks for replacing non-standard functional blocks. For example, the optimization and validation module 116 may be configured to generate a standard functional block for a given functional block group based on the functional blocks in the functional block group. In some embodiments, generating a standard functional block for a functional block group may comprise identifying a functional block in the functional block group that satisfies one or more optimization parameters, described above (e.g., impact value, performance, and/or the like), as the standard functional block for the functional block group (e.g., identifying a functional block in the functional block group as the optimal functional block based on one or more optimization parameters). For example, in some embodiments, the optimization and validation module 116 may be configured to calculate the impact value for each unique functional block in a functional block group and apply the impact values and/or other optimization parameters to an optimization algorithm configured to optimize an objective function and generate optimization data comprising an optimal function block selected from the functional block group. The selected optimal functional block, for example, may be associated with lower impact value relative to the other functional blocks (or portion thereof).

Alternatively or additionally, in some embodiments, generating a standard functional block for a given functional block group may comprise generating an optimal functional block having a configuration that is different from the functional blocks in the functional block group as the standard functional block based on one or more optimization parameters (e.g., as described above).

The optimization and validation module 116 may be configured to identify an assembly within a given functional block group that is a non-standard functional block and generate optimization data for such assembly that reflects the standard functional block generated for the functional block group.

Alternatively or additionally, in some embodiments, optimizing an assembly comprises performing a component standardization-based optimization as described herein.

In some embodiments, the optimization and validation module 116 is configured to identifying a plurality of disparate components associated with a plurality of assemblies and a particular category of components. For example, in some embodiments, the optimization and validation module 116 is configured to generate a plurality of component groups using one or more clustering machine learning models. The optimization and validation module 116 may provide component data for each component from a plurality of disparate components as input to the clustering machine learning model. The clustering machine learning model may be configured to apply one or more clustering algorithms and/or techniques to the input component data to generate a plurality of component groups, each comprising one or more components from the plurality of components that are deemed similar. The optimization and validation module 116 may generate a standard component for each component group. For example, the optimization and validation module 116 may be configured to standardize the plurality of disparate components by generating a standard component for each component group.

In some embodiments, generating a standard component for a component group may comprise identifying a component in the component group that satisfies one or more optimization parameters as the standard component for the component group. Alternatively or additionally, in some embodiments, generating a component for a given component group may comprise identifying a component that is different from the components in the component group as the standard component based on one or more optimization parameters.

The optimization and validation module 116 may be configured to identify assemblies and/or related assets that include a non-standard component and generate optimization data for such assembly and/or related asset, wherein the optimization data comprises a corresponding standard component generated for the component group associated with the non-standard component for the assembly or related asset.

Alternatively or additionally, in some embodiments, optimizing an assembly comprises performing a modularization-based optimization as described herein. For example, in some embodiments, the optimization and validation module 116 may be configured to modularize assemblies by replacing components of an assembly with fewer components to reduce the complexity of assemblies, size (e.g., dimensions), and/or impact value such as, for example, cost. For example, the optimization and validation module 116 may be configured to identify few modular components and/or functional blocks (e.g., replacing Wi-Fi modules with Wi-Fi integrated circuits (e.g., Wi-Fi chips), relacing voltage regulation component into compact power supply, and/or the like). In some embodiments, the optimization and validation module 116 may configured to, using one or more machine learning models, identify and optimize assembly layout, which in turn, results in size reduction and ease of manufacturing.

In some embodiments, the optimization and validation module 116 may be configured to execute one or more design simulations with respect to optimization data (e.g., comprising recommended component list data) for a target assembly to validate the optimization data. In some embodiments, the optimization and validation module 116 may be configured to provide optimization data (e.g., corresponding to updated assembly design) to a client computing entity in response to indication of the outcome/result of the one or more design simulations being a pass indication. In some embodiments, the optimization and validation module 116 may be configured such that optimization data is not provided to client computing entities in response to the indication of the outcome/result of the one or more design simulations being a fail indication. In some embodiments, in response to indication of an outcome/result of the one or more design simulations being a fail indication, the optimization and validation module 116 may be configured to cause and/or initiate optimization operation to be performed to regenerate optimized assembly design for the target assembly or group of assemblies.

In some embodiments, the optimization and validation module 116 includes or otherwise implements an adaptive learning framework and/or technique, where the machine learning models configured to generate optimization data are further configured to predict the outcome of the one or more design simulations for optimization data generated by the machine learning models. Optimization data may comprise one or more modifications to an initial component list (e.g., corresponding to an initial assembly design) such as replacement of one or more components in the initial assembly design with selected replacement components, replacement of one or more functional blocks in the initial assembly design with one or more standard functional blocks, replacement of one or more components in the initial assembly design with modular components, redesign of the layout of the initial assembly design, and/or the like.

In some embodiments, the one or more design simulations comprise physics-based simulations such as signal integrity simulation, power integrity simulation, thermal analysis, reliability analysis, EMI/EMC analysis such as electromagnetic interference and/or electromagnetic compatibility simulation, DRC, network analysis, and/or the like. The one or more design simulations may be performed to determine if the optimization data satisfies the requirements of asset(s) that utilize or otherwise include the target assembly associated with the optimization data.

The one or more machine learning models may be configured to learn updates (e.g., modifications) to an assembly design that would pass the corresponding design simulation(s) (e.g., that would result in a successful simulation) when such design simulation(s) are performed on the updated assembly that includes such updates. Alternatively or additionally, the one or more machine learning models may be configured to learn updates to an assembly design that would fail the corresponding design simulation(s) (e.g., result in a failed simulation) when such simulation(s) are performed on the updated assembly that includes such updates.

The one or more machine learning models may be configured, trained, and/or the like to learn patterns of assembly modifications/updates that pass or fail a design simulation operation (e.g., physics-based simulation) based on historical data (e.g., without explicitly running the simulations). In some embodiments, the adaptive learning framework and/or technique includes a feedback mechanism to feed back (e.g., provide) the outcome/result of design simulation(s) to the one or more machine learning model(s) such that the one or more machine learning model(s)) learn the pattern(s) of assembly changes/modifications that pass or fail the design simulation(s).

By using adaptive learning techniques to predict the outcome of a design simulations and providing feedback to the machine learning model configured to generate the updated design or representation thereof, example embodiments improve the accuracy of such machine learning models and optimization systems, which otherwise may not be achievable or feasible. For example, it may be impractical to run/execute the multiple simulations needed for each assembly. Further, by learning the pattern of assembly modifications that pass or fail a simulation and predicting the outcome of design simulation for an updated assembly based on the learned pattern, at least some embodiments of the present disclosure may reduce the number of design simulations needed for validation or obviate the need to perform such design simulations, which in turn increases efficiencies, reduces resource usage, and reduces latency with respect to optimization and implementation of assembly redesign.

In some embodiments, the optimization and validation module 116 may be configured to transmit optimization data generated by the optimization and validation module 116 to one or mor client computing entities. In some embodiments, the optimization and validation module 116 may be configured to cause rendering of a user interface (e.g., on a client computing entity) comprising the output optimization data.

In some embodiments, the optimization and validation module 116 may be configured to cause redesign of a target assembly based on the optimization data. For example, the optimization and validation module 116 may be configured to transmit instructions to one or more systems and/or devices configured to cause redesign of the target assembly. In some embodiments, redesign of the target assembly may include one or more of generating design data for the target assembly, generating electronic representation of a design of an assembly (e.g., ECAD or the like), generating schematic of an assembly, generating a prototype of an assembly, generating a working assembly, transmitting instructions configured to cause replacement of one or more components of an assembly, and/or the like.

In various embodiments, the optimization and validation module 116 may be configured to provide one or more user interface for users, where insights may be provided via the one or more user interfaces. For example, the user interface may be configured to function as a front-end for users such as, for example, value engineers and/or component engineers, to look at various insights and customize the process of optimization.

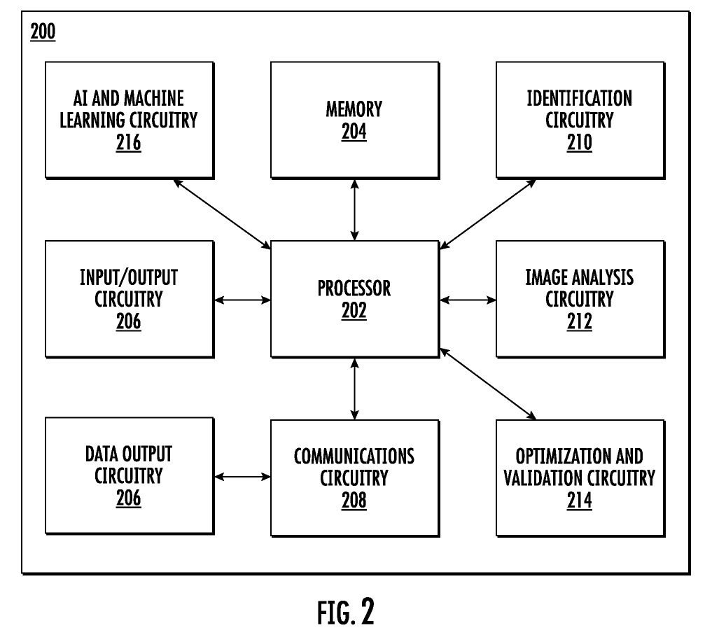

FIG. 2 illustrates a block diagram of an example apparatus that may be specially configured in accordance with at least one example embodiment of the present disclosure. Specifically, FIG. 2 depicts an example optimization and validation apparatus 200 (“apparatus 200”) specially configured in accordance with at least some example embodiments of the present disclosure. In some embodiments, the computing system 140 and/or a portion thereof is embodied by one or more system(s), such as the apparatus 200 as depicted and described in FIG. 2. The apparatus 200 includes processor 202, memory 204, input/output circuitry 206, communications circuitry 208, identification circuitry 210, image analysis circuitry 212, optimization and validation circuitry 214, AI and machine learning circuitry 216, and/or data output circuitry 218. In some embodiments, the apparatus 200 is configured, using one or more of the sets of circuitry embodied by processor 202, memory 204, input/output circuitry 206, communications circuitry 208, identification circuitry 210, image analysis circuitry 212, optimization and validation circuitry 214, AI and machine learning circuitry 216, and/or data output circuitry 218 to execute and perform the operations described herein.

In general, the terms computing entity (or “entity” in reference other than to a user), device, system, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably. In this regard, the apparatus 200 embodies a particular, specially configured computing entity transformed to enable the specific operations described herein and provide the specific advantages associated therewith, as described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), network interface(s), storage medium(s), and/or the like, to perform their associated functions, such that duplicate hardware is not required for each set of circuitry. In some examples, the use of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware only, software only, or a combination of hardware and software. For example, in some embodiments, “circuitry” includes processing circuitry, storage media, network interfaces, input/output devices, and/or the like. Alternatively or additionally, in some embodiments, other elements of the apparatus 200 provide or supplement the functionality of another particular set of circuitry. For example, the processor 202 in some embodiments provides processing functionality to any of the sets of circuitry, the memory 204 provides storage functionality to any of the sets of circuitry, the communications circuitry 208 provides network interface functionality to any of the sets of circuitry, and/or the like.

In some embodiments, the processor 202 (and/or co-processor or any other processing circuitry assisting or otherwise associated with the processor) is/are in communication with the memory 204 via a bus for passing information among components of the apparatus 200. In some embodiments, for example, the memory 204 is non-transitory and may include, for example, one or more volatile and/or non-volatile memories. In other words, for example, the memory 204 in some embodiments includes or embodies an electronic storage device (e.g., a computer readable storage medium). In some embodiments, the memory 204 is configured to store information, data, content, applications, instructions, or the like, for enabling the apparatus 200 to carry out various functions in accordance with example embodiments of the present disclosure.

The processor 202 may be embodied in a number of different ways. For example, in some example embodiments, the processor 202 includes one or more processing devices configured to perform independently. Additionally or alternatively, in some embodiments, the processor 202 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the apparatus 200, and/or one or more remote or “cloud” processor(s) external to the apparatus 200.

In an example embodiment, the processor 202 is configured to execute instructions stored in the memory 204 or otherwise accessible to the processor. Alternatively or additionally, the processor 202 in some embodiments is configured to execute hard-coded functionality. As such, whether configured by hardware or software methods, or by a combination thereof, the processor 202 represents an entity (e.g., physically embodied in circuitry) capable of performing operations according to an embodiment of the present disclosure while configured accordingly. Alternatively or additionally, as another example in some example embodiments, when the processor 202 is embodied as an executor of software instructions, the instructions specifically configure the processor 202 to perform the algorithms embodied in the specific operations described herein when such instructions are executed.

In some embodiments, the apparatus 200 includes input/output circuitry 206 that provides output to the user and, in some embodiments, to receive an indication of a user input. In some embodiments, the input/output circuitry 206 is in communication with the processor 202 to provide such functionality. The input/output circuitry 206 may comprise one or more user interface(s) and in some embodiments includes a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a client device and/or other display associated with a user.

In some embodiments, the apparatus 200 includes communications circuitry 208. The communications circuitry 208 includes any means such as a device or circuitry embodied in either hardware or a combination of hardware and software that is configured to receive and/or transmit data from/to a network and/or any other device, circuitry, or module in communication with the apparatus 200. In this regard, in some embodiments the communications circuitry 208 includes, for example, a network interface for enabling communications with a wired or wireless communications network. Additionally or alternatively in some embodiments, the communications circuitry 208 includes one or more network interface card(s), antenna(s), bus(es), switch(es), router(s), modem(s), and supporting hardware, firmware, and/or software, or any other device suitable for enabling communications via one or more communications network(s). Additionally or alternatively, the communications circuitry 208 includes circuitry for interacting with the antenna(s) and/or other hardware or software to cause transmission of signals via the antenna(s) or to handle receipt of signals received via the antenna(s). In some embodiments, the communications circuitry 208 enables transmission to and/or receipt of data from user device, one or more asset(s) or accompanying sensor(s) , and/or other external computing device in communication with the apparatus 200.

In some embodiments, the apparatus 200 includes an identification circuitry 210. The identification circuitry 210 includes hardware, software, firmware, and/or a combination thereof, that supports intelligent assembly optimization and validation according to one or more techniques of the present disclosure. For example, in some embodiments, the identification circuitry 210 includes hardware, software, firmware, and/or a combination thereof, configured to, with the processing circuitry 202, input/output circuitry 206 and/or communications circuitry 208, perform one or more functions associated with the identification module 112 described above with respect to FIG. 1. In some embodiments, the identification circuitry 210 includes a separate processor, specially configured field programmable gate array (FPGA), or a specially programmed application specific integrated circuit (ASIC).

In some embodiments, the apparatus 200 includes an image analysis circuitry 212. The image analysis circuitry 212 includes hardware, software, firmware, and/or a combination thereof, that supports intelligent assembly optimization and validation according to one or more techniques of the present disclosure. For example, in some embodiments, the Image analysis circuitry 212 includes hardware, software, firmware, and/or a combination thereof, configured to, with the processing circuitry 202, input/output circuitry 206 and/or communications circuitry 208, perform one or more functions associated with the image analysis module 114 described above with respect to FIG. 1. In some embodiments, the image analysis circuitry 212 includes a separate processor, specially configured field programmable gate array (FPGA), or a specially programmed application specific integrated circuit (ASIC).

In some embodiments, the apparatus 200 includes an optimization and validation circuitry 214. The optimization and validation circuitry 214 includes hardware, software, firmware, and/or a combination thereof, that supports intelligent assembly optimization and validation according to one or more techniques of the present disclosure. For example, in some embodiments, the optimization and validation circuitry 214 includes hardware, software, firmware, and/or a combination thereof, configured to, with the processing circuitry 202, input/output circuitry 206 and/or communications circuitry 208, perform one or more functions associated with the optimization and validation module 116 described above with respect to FIG. 1. In some embodiments, the optimization and validation circuitry 214 includes a separate processor, specially configured field programmable gate array (FPGA), or a specially programmed application specific integrated circuit (ASIC).

In some embodiments, the apparatus 200 includes AI and machine learning circuitry 216 In some embodiments, the AI and machine learning circuitry may include hardware, software, firmware, and/or a combination thereof designed and/or configured to request, receive, process, generate, and transmit data, data structures, control signals, and electronic information for training and executing a trained AI and/or machine learning model (AI/ML model) configured to facilitate the operations and/or functionalities described herein. For example, in some embodiments the AI and machine learning circuitry 216 includes hardware, software, firmware, and/or a combination thereof, that identifies training data and/or utilizes such training data for training a particular machine learning model, AI, and/or other model to generate particular output data based at least in part on learnings from the training data. Additionally or alternatively, in some embodiments, the AI and machine learning circuitry 216 includes hardware, software, firmware, and/or a combination thereof, that embodies or retrieves a trained machine learning model, AI and/or other specially configured model utilized to process inputted data. Additionally or alternatively, in some embodiments, the AI and machine learning circuitry 216 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

In some embodiments, the apparatus 200 may include a data output circuitry 218. In some embodiments, the data output circuitry 218 may include hardware, software, firmware, and/or a combination thereof, that configures and/or generates an output based at least in part on data processed by the apparatus 200. In some embodiments, the data output circuitry 218 includes hardware, software, firmware, and/or a combination thereof, that generates a particular report based at least in part on output of an optimization and/or validation operation according to one or more techniques of the present disclosure, for example where the report is generated based at least in part on a particular reporting protocol. Additionally or alternatively, in some embodiments, the data output circuitry 218 includes hardware, software, firmware, and/or a combination thereof, that configures a particular output data object, output data file, and/or user interface for storing, transmitting, and/or displaying. For example, in some embodiments, the data output circuitry 218 generates and/or specially configures a particular data output for transmission to another system sub-system for further processing. Additionally or alternatively, in some embodiments, the data output circuitry includes hardware, software, firmware, and/or a combination thereof, that causes rendering of a specially configured user interface based at least in part on data received by and/or processing by the apparatus 200.

In some embodiments, two or more of the sets of circuitries 202-218 are combinable. Alternatively or additionally or in some embodiments, one or more of the sets of circuitries embodying processor 202, memory 204, input/output circuitry 206, communications circuitry 208, identification circuitry 210, image analysis circuitry 212, optimization and validation circuitry 214, AI and machine learning circuitry 216, and/or data output circuitry 218 perform some or all of the functionality described as associated with another component. For example, in some embodiments, two or more of the sets of circuitry embodied by processor 202, memory 204, input/output circuitry 206, communications circuitry 208, identification circuitry 210, image analysis circuitry 212, optimization and validation circuitry 214, AI and machine learning circuitry 216, and/or data output circuitry 218 are combined into a single module embodied in hardware, software, firmware, and/or a combination thereof. Similarly, in some embodiments, one or more of the sets of circuitry, for example identification circuitry 210, image analysis circuitry 212, optimization and validation circuitry 214, AI and machine learning circuitry 216, and/or data output circuitry 218 is/are combined with the processor 202, such that the processor 202 performs one or more of the operations described above with respect to each of these sets of circuitry embodied by the identification circuitry 210, image analysis circuitry 212, optimization and validation circuitry 214, AI and machine learning circuitry 216, and/or data output circuitry 218.

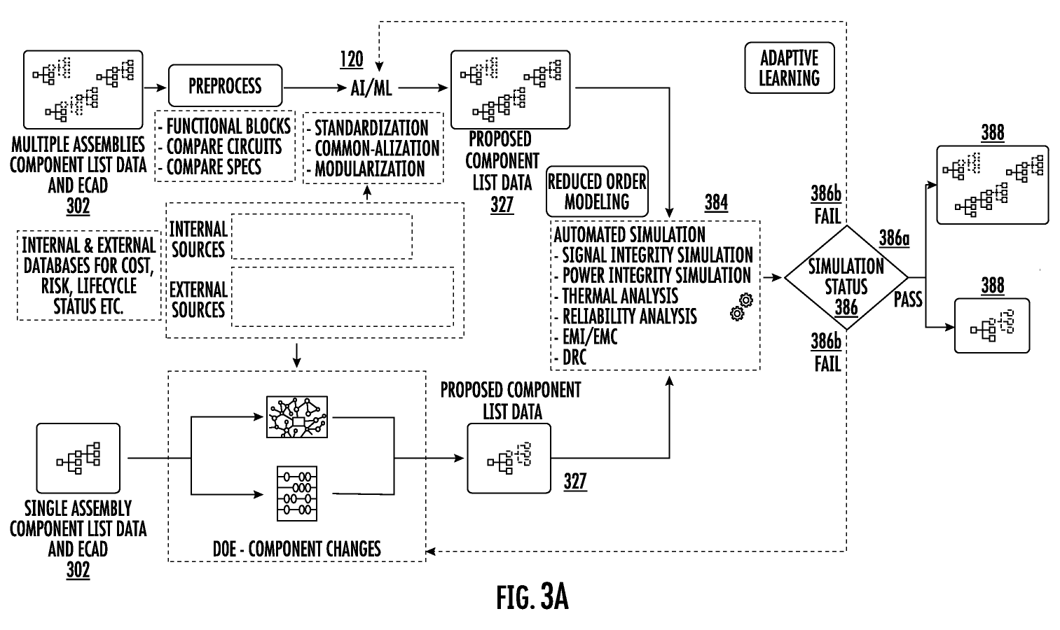

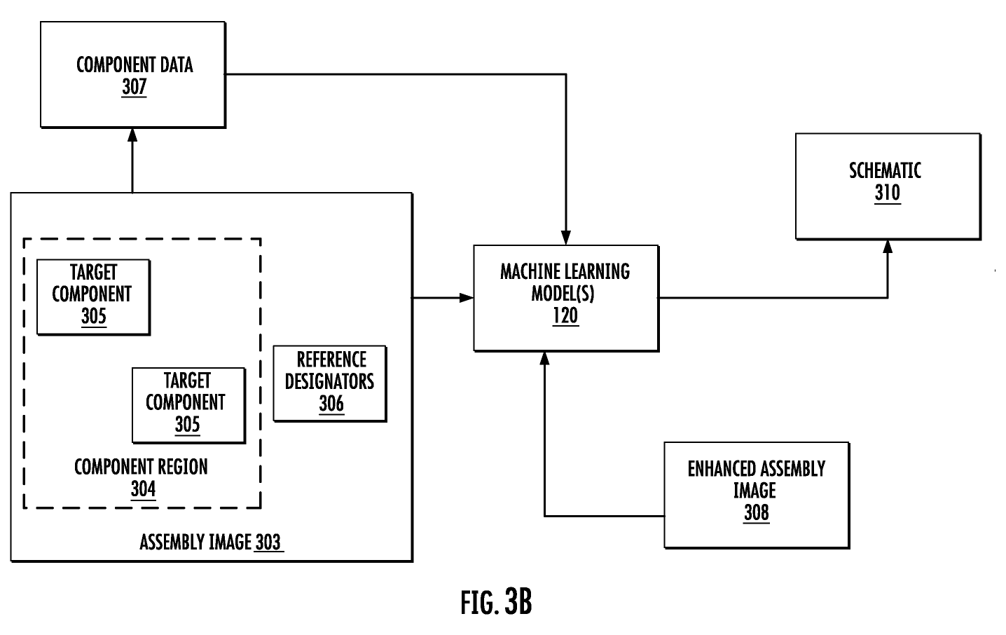

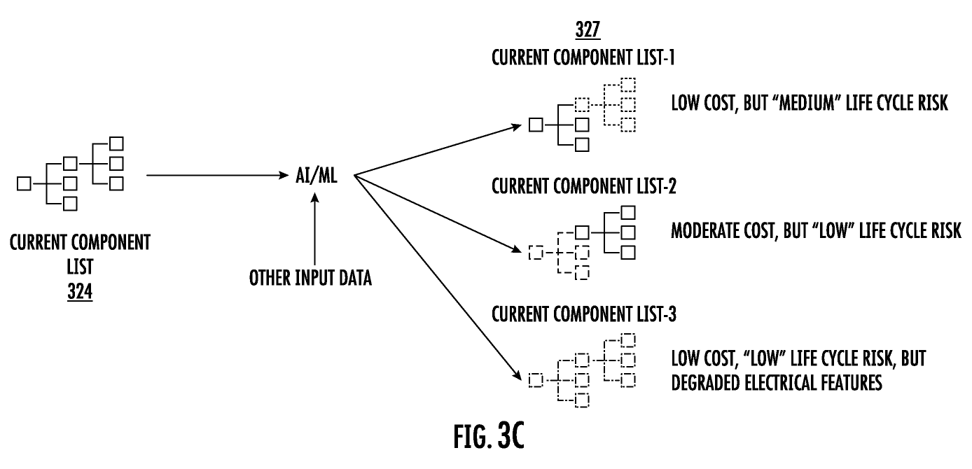

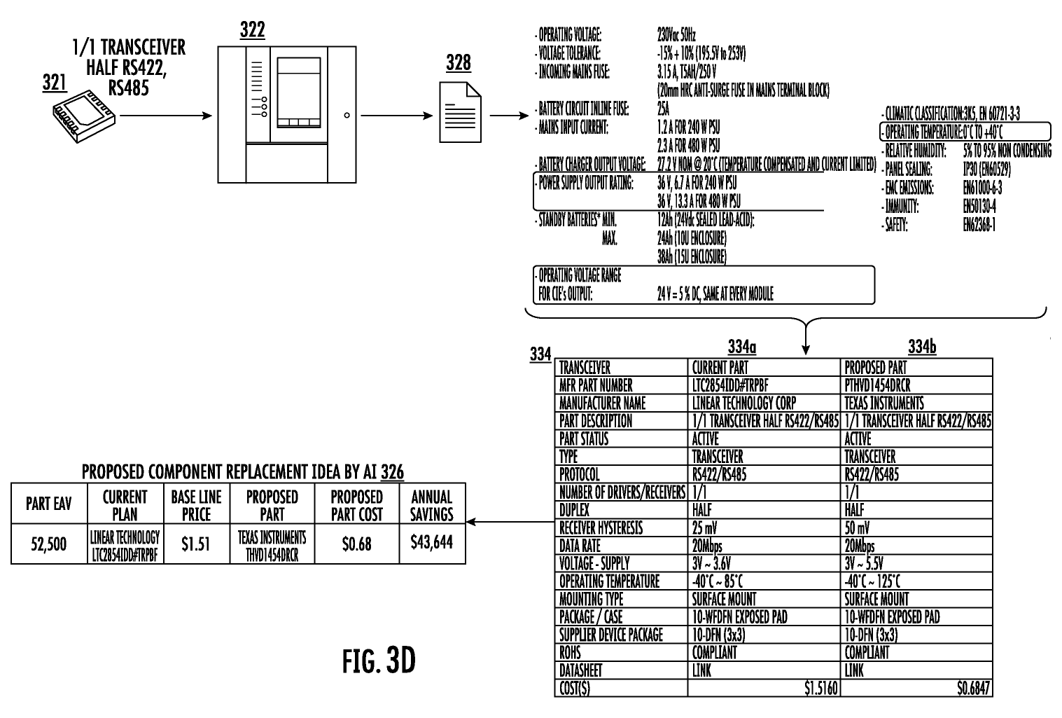

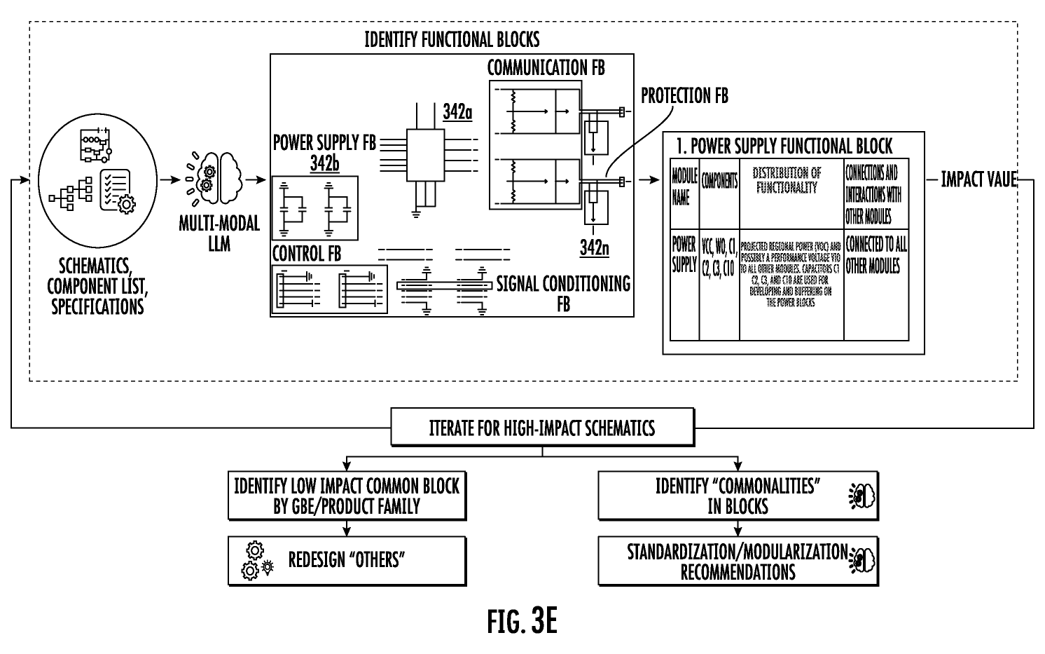

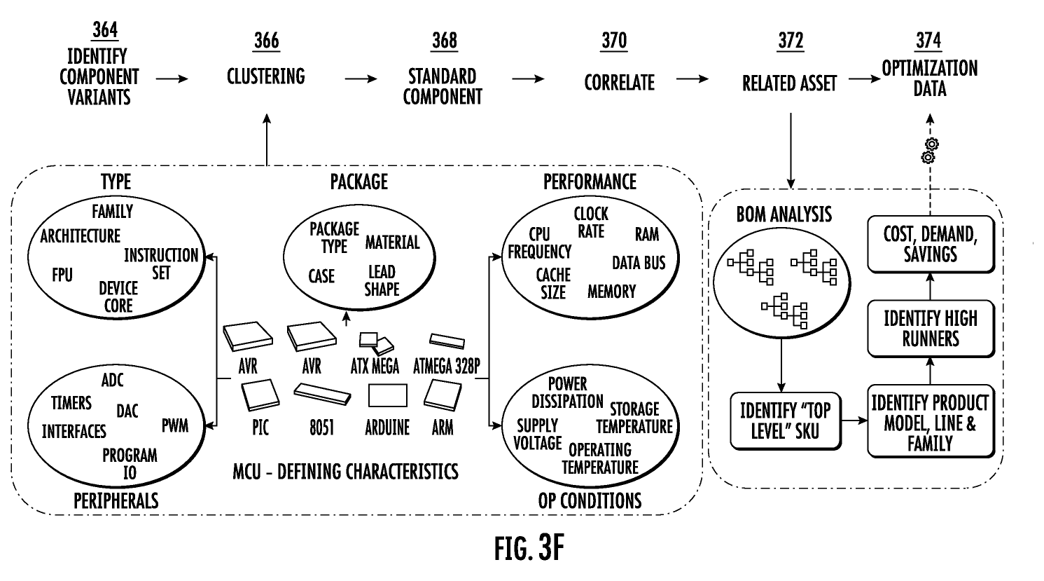

FIG. 3a illustrates example visualization of data structures, modules, and processes for end-to-end assembly optimization and simulation in accordance with at least one example embodiment of the present disclosure. Assembly design optimization and simulation may be performed for a single assembly or multiple assemblies in accordance with one or more techniques described herein.

In some embodiments, input data 302 comprising component list data and/or ECAD for a single target assembly or a plurality of target assemblies is identified, received, and/o obtained. For example, input data 302 for design optimization and simulation for a single target assembly may include component list data and/or ECAD data for the target assembly, while input data 302 for design optimization and simulation for a plurality of target assemblies may include component list data and/or ECAD data for each target assembly of the plurality of target assemblies.

In some embodiments, a single target assembly or a plurality of target assemblies is identified from an aggregated dataset associated with one or more assets. In some embodiments, the aggregated dataset is accessed, received, and/or generated based on data maintained via one or more data sources such as, for example, asset lifecycle management data (PLM data) and enterprise resource planning (ERP) data. In some embodiments, the aggregated dataset is accessed, received, and/or generated in response to an assembly optimization request received from a client computing entity. In some embodiments, an assembly optimization request is signal, data, message (e.g., an inter-service message, intra-service message, network message, etc.), and/or computer readable instructions descriptive of a request to generate optimization data for an assembly or group of assemblies.

The aggregated dataset may comprise assembly identifier(s) and/or other data associated with assembly(s) used in at least one asset of the one or more assets. The one or more assets may be associated with one or more entities (e.g., one or more enterprises, organizations, processing plant, assembling plant, and/or the like). For example, the assembly(s) may be included in one or more assets of one or more entities. An asset may be an equipment, machine, device, and/or the like. An assembly may comprise one or more components disposed and/or formed on and/or in an electronic board comprising a substrate. In various examples, an assembly comprises a plurality of components, at least a portion of which are connected via traces (e.g., conductive traces).

In some embodiments, an assembly identifier is one or more items or elements by which an assembly may be uniquely identified from other assemblies or by which a group of assemblies may be uniquely identified from other assemblies (or other assembly groups). An assembly identifier may be in the form of text string(s), numerical character(s), alphabetical character(s), alphanumeric code(s), American Standard Code for information Interchange (ASCII) characters(s), and/or the like.

In some embodiments, a component of an assembly may be associated with a component identifier. In some embodiments, a component identifier is one or more items or elements by which a component may be uniquely identified from other components or by which a group of components may be uniquely identified from other components (or other component groups). A component identifier may be in the form of text string(s), numerical character(s), alphabetical character(s), alphanumeric code(s), American Standard Code for information Interchange (ASCII) characters(s), and/or the like.

In some embodiments, the single target assembly or plurality of target assemblies may be identified from the aggregated dataset based on selection criteria. In some embodiments, selection criteria comprises one or more features associated with assemblies and that may be used to determine if an assembly qualifies for optimization. Non-limiting examples of such features include assembly impact value (e.g., impact value of an assembly such as, for example, cost, resource usage, and/or the like associated with the assembly), related asset impact value (e.g., impact value for an asset that that includes the assembly such as, for example, cost, resource usage, and/or the like associated with the related asset), assembly risk level (e.g., risk level associated with an assembly such as, for example, safety risk, end of life risk, and/or the like), assembly performance (e.g., performance of an assembly with respect to one or more KPIs), assembly physical characteristics (e.g., weight, dimension, and/or the like of an assembly), assembly usage (e.g., actual and/or predicted demand for an assembly based on, for example, sales, inventory and operations planning (SIOP)), assembly predicted end of life (e.g., predicted end of life for an assembly) related asset end of life (predicted end of life for an asset that includes the assembly), predicted end of life for assembly component(s), and/or the like), historical data such as, for example, historical procurement spend, and/or the like, component list data such as, for example, bill of materials (BOM) associated with an assembly or related asset. In some embodiments, the selection criteria is configurable.

In some embodiments, a target assembly is an assembly identified as a candidate for optimization and/or includes one or more components identified as a candidate for optimization based on selection criteria. In some embodiments, data associated with an assembly represented in the aggregated dataset (e.g., assembly identifier thereof) is analyzed to determine if the assembly satisfies the selection criteria. Such data may include data for the assembly corresponding to the one or more features described above.

In some embodiments, input data 302 for optimizing an assembly (e.g., single target assembly or each of a plurality of target assemblies) may include schematic for the assembly. FIG. 3b illustrates example visualization of data structures, modules, and processes for generating assembly schematic in accordance with at least one example embodiment of the present disclosure.

In some embodiments, assembly schematic 310 is generated for a target assembly using at least one of one or more machine learning models 120. In some embodiments, the one or more machine learning models 120 comprise one or more image recognition and analysis models such as computer vision models. The image recognition and analysis models, for example, may include one or more advanced computer vision models. Alternatively or additionally, in some embodiments, the one or more machine learning models comprise one or more large language models such as multi-modal large language models.

In some embodiments, an image 303 of a target assembly is captured using one or more imaging devices (e.g., camera, and/or the like). The assembly image 303 may comprise a visual representation of the target assembly, including the component(s) of the target assembly and traces connecting the components.

In some embodiments, one or more component regions 304 is identified for the target assembly based on the assembly image 303. In some embodiments, a component region may comprise a plurality of components connected via traces. In some embodiments, a component region may represent a functional block in an assembly. In some embodiments, an image recognition and analysis model, such as a computer vision model, is leveraged to identify the one or more component regions 304. The image recognition and analysis model may be configured to receive the assembly image 303 as input and perform image analysis on the assembly image 303 to identify the one or more component regions 304. For example, the predictive computing entity 110 (e.g., image analysis module 114 thereof) may input the assembly image 303 into the image recognition and analysis model, and the image recognition and analysis model may generate an output that identifies the one or more component regions 304. In some embodiments, the image recognition and analysis model is configured to identify the one or more component regions 304 by identifying portions of the target assembly having components connected through traces.

In some embodiments, identifying data for one or more components of the target assembly is generated. The one or more components may include components in the one or more identified component regions 304. In some embodiments, the one or more components or a portion of the one or more components may represent a target component 305 based on data associated with the respective component (e.g., issue diagnosed for a component, and/or the like). In some embodiments, the identifying data for a given component comprises a part number for the component (e.g., a manufacturer part number or the like). Alternatively or additionally, in some embodiments, the identifying data for a given component comprises a reference designator 306 (See FIG. 3b) for the component. A reference designator may comprise one or more items or elements by which a class of a component may be identified from other component class. A reference designator may be in the form of text string(s), numerical character(s), alphabetical character(s), alphanumeric code(s), American Standard Code for information Interchange (ASCII) characters(s), and/or the like. In some examples, a reference designator may be displayed or otherwise included on the electronic board of an assembly. It would be understood that the identifying data may comprise other data that may be used to identify a component or obtain data associated with the component.

In some embodiments, component data 307 is generated for each the one or more components identified or a portion thereof. The component data 307, for example, may generated for a target component. The component data 307 for a given target component may comprise specification data for the target component. The specification data for a target component may comprise specification (e.g., values) for one or more operating parameters (e.g., voltage, temperature, and/or the like) and/or other characteristics of the target component.

In some embodiments, generating the component data 307 for a target component may comprise retrieving specification data (or portion thereof) for the target component from one or more databases based on the component identifier and/or identifying data (e.g., part number, reference designator, or the like) associated with the target component. Alternatively or additionally, in some embodiments, generating the component data 307 for a target component may comprise receiving the specification data (or portion thereof) from one or more external data sources (e.g., third-party systems) based on the component identifier and/or identifying data.

In some embodiments, an image enhancement operation is performed on the assembly image 303 (or portion thereof), using the image recognition and analysis model (e.g., computer vision model or the like), to generate an enhanced assembly image 308 such that visual representations of the connections between the one or more components are enhanced and may be analyzed to generate an assembly schematic for the target assembly.

In some embodiments, an assembly schematic 310 is generated for the target assembly, using a large language machine learning model based on the identified one or more component regions 304, the component data 307, the reference designator(s) 306 (or other identifying data), and/or enhanced assembly image 308 for the target assembly. In some embodiments, the large language model is a multi-modal large language model configured to generate a schematic for an assembly in accordance with one or more guidelines and/or knowledge base such as assembly design guidelines, electrical laws and engineering conventions. In some embodiments, the component data 307 for the target component(s), the reference designator(s) 306 for the target component(s), enhanced assembly image 308, assembly design guidelines, electrical laws and engineering guidelines are input into the large language model. The large language model (e.g., multi-modal large language model) may analyze the enhanced assembly image 308 and component data 307 (e.g., specification data thereof) with respect to the assembly design guidelines and electrical laws and engineering guidelines and generate an output comprising an assembly schematic 310 for the target assembly.

In some embodiments, optimization data is generated for the target assembly (or group of target assemblies) for the target assembly in accordance with one or more optimization techniques and/or operations described herein. In some embodiments, the optimization data comprises proposed/recommended changes to each target assembly of one or more target assemblies.

FIGS. 3c-3f each illustrate example visualization of data structures, modules, and processes for assembly optimization in accordance with at least one example embodiment of the present disclosure. It would be appreciated that the various data depicted in the Figures, including FIGS. 3c-3f are provided as examples and not intended to be limiting. In particular, FIGS. 3c-3d illustrate example visualization of data structures, modules, and processes for component replacement-based optimization in accordance with at least one example embodiment of the present disclosure, FIG. 3e illustrates example visualization of data structures, modules, and processes for functional block-based optimization in accordance with at least one example embodiment of the present disclosure, and FIG. 3f illustrates example visualization of data structures, modules, and processes for component standardization-based optimization in accordance with at least one example embodiment of the present disclosure.

Referencing FIGS. 3c-3d, in some embodiments, a component replacement-based optimization operation may be performed to determine optimal component(s) for an assembly. The output of the component replacement-based optimization may comprise a recommendation to replace at least one of the components of the target assembly with a replacement component identified as an optimal component for the assembly based on one or more optimization parameters and/or optimization constraints. The output of the component replacement-based optimization, for example, may comprise component identifiers for one or more replacement components for a target component. Such one or more replacement components may be identified in accordance with one or more optimization techniques of the present disclosure as optimal components for the assembly.

In some embodiments, a component of the target assembly may be identified as a target component for replacement based on one or more issues diagnosed as being associated with the respective components. Non-limiting examples of such issues include assembly faults (e.g., performance faults and/or defects), risk factors (e.g., safety risk, obsolescence risk, availability risk, end of life risk, and/or the like), above predetermined thresholds, impact value above predetermined threshold, performance data (e.g., KPIs) below predetermined thresholds.

As depicted in FIG. 3c, in some embodiments, the output of a component replacement-based optimization operation may comprise a plurality of recommended component list data, each comprising one or more replacement components. As shown in FIG. 3a, in some embodiments, the output of a component replacement-based optimization operation may comprise a single recommended component list data.

As depicted in FIGS. 3a and 3c, component list data 324 (e.g., initial component list data) for the target assembly may be input into a machine learning model, such as an optimization machine learning model configured to analyze the component list data 324 and generate optimization data comprising one or more recommended component list data 327. Additionally, in some embodiments, the assembly schematic 310 for the target assembly and/or ECAD for the target assembly may be input to the machine learning model, wherein the machine learning model may be configured to analyze the component list data 324 and the assembly schematic 310 and/or ECAD to generate one or more recommended component list data. In some embodiments, recommended component list data 327 may generated using design of experiment (DOE) techniques.

A recommended component list data 327 may comprise one or more recommended replacement components for one or more components of the target assembly identified as a target component based on diagnosed issue(s) associated with the respective component (as described above). A recommended component list data 327 may represent optimal component list data for a target assembly that maximizes one or more optimization parameters (as described above) or portion thereof while taking into account one or more optimization constraints (as described above).

In some embodiments, recommended replacement component may be identified for a target component 321 in accordance with FIG. 3d. As depicted in FIG. 3d, in some embodiments, one or more related assets 322 is identified for the target assembly comprising the target component. In some embodiments, the related asset 322 is an asset that includes or otherwise uses the target assembly.

In some embodiments, specification data 328 for the related asset 322 is retrieved from a specification database or received from an external data source (e.g., a third-party system). The specification data 328 for the related asset 322 may be retrieved and/or received based on the asset identifier and/or part number associated with the related asset 322. The specification data 328 for the related asset 322 may comprise specification for one or more operating parameters (e.g., voltage, temperature, and/or the like) and/or other characteristics of the related asset. For example, the specification data 328 for a related asset may comprise electrical and operation conditions information for the related asset 322.

In some embodiments, one or more candidate replacement components are identified for a target component 321. In some embodiments, at least one of the one or more machine learning models 120 may be leveraged to identify candidate replacement components for a target component based on specification data for the target component and/or specification data for the one or more related asset 322. For example, at least one of the one or more machine learning models may be configured to receive input data comprising specification data for the target component 321 and/or specification data for the one or more related assets 322 and generate data comprising one or more component identifiers for candidate replacement components for the target component at least in part by analyzing the specification data for the target component and/or specification data for the one or more related asset 322.

In some embodiments, comparison data 334 is generated for each candidate replacement component. The comparison data 334 for a replacement component may comprise data that describes similarities and differences between the target component and the candidate replacement component. For example, the comparison data 334 may comprise data that describes similarities and differences between specification data 334a for the target component and the specification data 334b for the candidate replacement component. In some embodiments, a machine learning model may be leveraged to generate the comparison data 334 for a candidate replacement component. In some embodiments, such machine learning model may comprise a component of the composite design optimization machine learning model.

In some embodiments, one or more replacement components from the candidate replacement components is selected based on the comparison data 334 for the candidate replacement component(s) and the specification data 328 for the related asset using a machine learning model such as a large language model. In some embodiments, the machine learning model may comprise an optimization algorithm and/or represent an optimization machine learning model configured to optimize an objective function based on the comparison data 334 and specification data 328. The objective function may comprise one or more optimization parameters and/or optimization constraints. In some embodiments, optimizing the objective function comprises correlating the specification data 328 for a related asset 322 with the comparison data 334 for the candidate replacement components (e.g., at least one of the candidate replacement components) with respect to maximize the one or more optimization parameters (as described above) while taking into account the one or more optimization constraints. The output 326 (e.g., optimization data) of the machine learning model (e.g., optimization machine learning model) may comprise data that describes at least one replacement component from the candidate replacement component(s) that represents an optimal component for replacing the target component 321. In some embodiments, as described above, the optimization constraints may comprise specification for one or more operating parameters and/or other characteristics of the related asset 322 and/or target component 321.

FIG. 3e illustrate example visualization of data structures, modules, and processes for functional block-based optimization in accordance with at least one example embodiment of the present disclosure. In some embodiments, one or more target assemblies from a plurality of assemblies may be optimized based on functional blocks associated with the plurality of assembly in accordance with functional block-based optimization techniques described herein.

In some embodiments, functional block-based optimization comprises identifying non-standard functional blocks based on functional blocks associated with a plurality of assemblies and generating standard functional block for replacing a non-standard functional block in an assembly. In some embodiments, at least one of the one or more machine learning models 120 may be leveraged to perform functional block type optimization. In some embodiments, a standard functional block is a functional block that may be used across multiple assemblies.

Referencing FIG. 3e, in some embodiments, one or more functional blocks 342a-n associated with each assembly of a plurality of assemblies are identified. In some embodiments, functional block(s) 342a-n associated with an assembly is identified using at least one of the one or more machine learning models 120 and based on analysis of an assembly schematic 310 for the assembly and/or ECAD for the assembly, component list data associated with the assembly, electrical connection data (e.g., netlist, and/or the like) associated with the assembly, and/or other relevant data.

In some embodiments, clustering data comprising data that describes similarities and/or differences among the functional blocks (or a portion thereof) is generated. In some embodiments, the functional blocks 342a-n for the plurality of assemblies are grouped based on the clustering data. For example, the plurality of assemblies may be grouped into one or more groups (e.g., functional block groups) using one or more clustering techniques and/or clustering machine learning model (e.g., comprising a clustering algorithm) configured to generate a plurality of groups based on similarities and/or differences between the functional blocks and assign each functional block to a corresponding group. In some embodiments, grouping the functional blocks may comprise generating a similarity score for pairs of functional blocks based on a similarity measure such as Euclidean distance measure, cosine similarity measure, and/or the like. In some embodiments, the clustering machine learning model is a component of the composite design optimization machine learning model.

In some embodiments, a standard functional block is generated for a functional block group. For example, a standard functional block may be generated for each functional block group generated. In some embodiments, a standard functional block for a given functional block group may be generated based on the functional blocks in the functional block group.

In some embodiments, generating a standard functional block for a functional block group may comprise identifying a functional block in the functional block group that satisfies one or more optimization parameters or subset thereof (e.g., as described above) as the standard functional block for the functional block group (e.g., identifying a functional block in the functional block group as the optimal functional block based on one or more optimization parameters or portion thereof. For example, the functional block(s) in a functional block group may be analyzed to determine if they satisfy the one or more optimization parameters.

Alternatively or additionally, in some embodiments, generating a standard functional block for a given functional block group may comprise generating an optimal functional block having a configuration that is different from the functional blocks in the functional block group as the standard functional block based on one or more optimization parameters or subset thereof.

In some embodiments, one or more functional blocks in a functional block is identified as a non-standard functional block. A non-standard functional block may describe a functional block having a configuration that is different from the standard functional block generated for the functional block group which the functional block is assigned. In some embodiments, a functional block may be compared to the standard functional block generated for the functional block group to determine if the functional block is a non-standard functional block. In some embodiments, a machine learning model may be configured to determine if a functional block is a standard functional block based on a similarity measure (e.g., Euclidean distance similarity measure, cosine similarity measure, and/or the like) for the functional block with respect to the standard functional block generated. In some embodiments, such machine learning model is a component of the composite design optimization machine learning model.

In some embodiments, an assembly associated with a non-standard functional block is identified as a target assembly. In some embodiments, optimization data comprising data that describes a standard functional block (or relevant portions of the standard functional block) for replacing the non-standard functional block (or a portion thereof) is generated for such target assembly based on the functional block group associated with the non-standard functional block. The optimization data, for example, may reflects the configuration (e.g., components, connections, and/or other characteristics) of the standard functional block generated for the functional block group associated therewith.

FIG. 3f illustrates example visualization of data structures, modules, and processes for component standardization-based optimization in accordance with at least one example embodiment of the present disclosure.

In some embodiments, a plurality of disparate components 364 associated with a plurality of assemblies and a particular category of components are identified. In some embodiments a plurality of component groups is generated using one or more clustering machine learning models 366. The component data for each component may be input to the clustering machine learning model. The clustering machine learning model may be configured to apply one or more clustering algorithms and/or techniques to the input component data to generate the plurality of component groups, each comprising one or more components from the plurality of components that are deemed similar. A standard component 368 may be generated for each component group. For example, the plurality of disparate components (e.g., component variants) may be standardized by generating a standard component for each component group.

In some embodiments, generating a standard component for a component group may comprise identifying a component in the component group that satisfies one or more optimization parameters as the standard component for the component group. Alternatively or additionally, in some embodiments, generating a component for a given component group may comprise identifying a component that is different from the components in the component group as the standard component based on one or more optimization parameters.

In some embodiments, a standard component is correlated with availability and/or usage data 370 (e.g., inventory and/or demand). In some embodiments, an assembly or related asset 322 associated with a non-standard component is identified by analyzing component list data such as, for example, bill or material (BOM). In some embodiments, optimization data 374 comprising corresponding standard component is generated for the identified assembly and/or related asset 322.

Returning to FIG. 3a, in some embodiments, a design simulation result 386 is optionally generated for a target assembly or each of a group of assemblies based on one or more design simulations 384 executed/run for the target assembly or the group of assemblies. Such design simulations may be executed/run to validate the optimization data for the respective target assembly. In some embodiments, at least one of the one or more design simulations 384 is a physics-based simulation. Non-limiting examples of the one or more design simulations include signal integrity simulation, power integrity simulation, thermal analysis, reliability analysis, electromagnetic interference and/or electromagnetic compatibility analysis, DRC, network analysis, and/or the like. The one or more design simulations may be performed to determine if the optimization data satisfies the requirements of asset(s) that utilize or otherwise include the target assembly associated with the optimization data.

The design simulation result 386 for a given target assembly may be a pass indication 386a or a fail indication 386b. In some embodiments, optimization data 388 (e.g., corresponding to updated assembly design) for each of the one or more target assemblies may be provided to one or more client computing entities or otherwise recommended in response to a pass indication 386a. In some embodiments, in response to a fail indication 386b, the machine learning models 120 may be directed to regenerate optimization data for the target assembly or group of assemblies.

In some embodiments, the design simulation results 386 is provided, as feedback, to the machine learning model(s) of the one or more machine learning models 120 configured for outputting optimization data to improve the accuracy of the machine learning models 120. Such machine learning models may be configured to learn patterns based on the simulation results 386 (e.g., without explicitly running the simulations). The machine learning models may be configured to learn updates (e.g., modifications) to an assembly design that would pass the corresponding design simulation(s) (e.g., that would result in a successful simulation) when such design simulation(s) are performed on the optimization data that includes such updates. Alternatively or additionally, the one or more machine learning models may be configured to learn updates to an assembly design that would fail the corresponding design simulation(s) (e.g., result in a failed simulation) when such simulation(s) are performed on the updated assembly that includes such updates.

In some embodiments, the one or more machine learning models may be trained based on historical data comprising previous optimization data and corresponding simulation result. The machine learning models may learn patterns of assembly modifications/updates that pass or fail a design simulation operation (e.g., physics-based simulation) based on the historical data (e.g., without explicitly running the simulations).

In some embodiments, the machine learning models may be configured to generate a design simulation result prediction for optimization data generated by the machine learning models and output the optimization data if the design simulation result prediction is positive prediction (e.g., indication that the optimization data would pass one or more design simulations. In some embodiments, the machine learning models are configured to regenerate optimization data (e.g., update design) if the design simulation result prediction is a negative prediction. For example, the machine learning models 120 may be configured to predict the result of the one or more design simulations for optimization data (e.g., corresponding to updated assembly design) without performing the one or more design simulations and determine if to output the optimization data based on the design simulation result prediction associated with the optimization data.

In some embodiments, at least one of the one or more design simulations 384 may not be performed for the optimization data for the at least one target assembly. For example, the one or more design simulations 384 may be performed for only a subset of the target assemblies for which optimization data is generated or for none of the target assemblies. By doing so, example embodiments improve the accuracy of such machine learning models and optimization systems, which otherwise may not be achievable or feasible. For example, it may be impractical to run/execute the simulations 384 needed for each assembly. Further, by learning the patterns of assembly modifications that pass or fail a design simulation and predicting the outcome of design simulation for an updated assembly (e.g., design simulation result prediction) based on the learned patterns (e.g., without explicitly running the simulations), at least some embodiments of the present disclosure may reduce the number of design simulations needed for validation or obviate the need to perform such design simulations, which in turn increases efficiencies, reduces resource usage, and reduces latency with respect to optimization and implementation of assembly redesign.

### EXAMPLE PROCESSES OF THE DISCLOSURE

Having described example systems and apparatuses, and data visualizations in accordance with the disclosure, example processes of the disclosure will now be discussed. It will be appreciated that each of the flowcharts depicts an example computer-implemented process that is performable by one or more of the apparatuses, systems, devices, and/or computer program products described herein, for example utilizing one or more of the specially configured components thereof.

Although the example processes/methods depicts a particular sequence of operations, the sequence may be altered without departing from the scope of the present disclosure. For example, some of the operations depicted may be performed in parallel or in a different sequence that does not materially affect the function of the processes.

The blocks indicate operations of each process/method. Such operations may be performed in any of a number of ways, including, without limitation, in the order and manner as depicted and described herein. In some embodiments, one or more blocks of any of the processes described herein occur in-between one or more blocks of another process, before one or more blocks of another process, in parallel with one or more blocks of another process, and/or as a sub-process of a second process. Additionally or alternatively, any of the processes in various embodiments include some or all operational steps described and/or depicted, including one or more optional blocks in some embodiments. With regard to the flowcharts illustrated herein, one or more of the depicted block(s) in some embodiments is/are optional in some, or all, embodiments of the disclosure. Optional blocks are depicted with broken (or “dashed”) lines. Similarly, it should be appreciated that one or more of the operations of each flowchart may be combinable, replaceable, and/or otherwise altered as described herein.

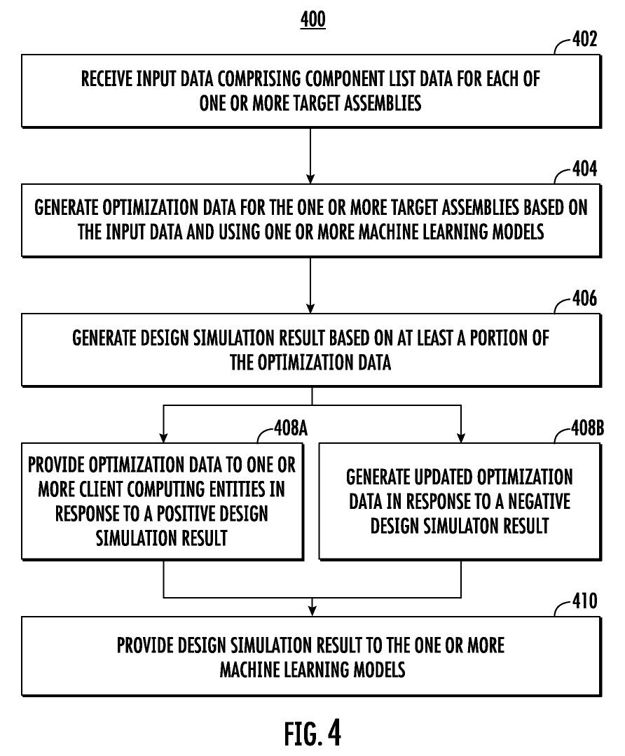

FIG. 4 illustrates a flowchart for simulation and AI-driven integrated framework for design optimization in accordance with at least one example embodiment of the present disclosure. In some embodiments, the process/method 400 is embodied by computer program code stored on a non-transitory computer-readable storage medium of a computer program product configured for execution to perform the process/method as depicted and described. Alternatively or additionally, in some embodiments, the process/method 400 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with separate component(s) of a network, external network(s), and/or the like, to perform one or more of the operation(s) as depicted and described. For purposes of simplifying the description, the process 400 is described as performed by and from the perspective of the apparatus 200.

Although the example process/method 400 depicts a particular sequence of operations, the sequence may be altered without departing from the scope of the present disclosure. For example, some of the operations depicted may be performed in parallel or in a different sequence that does not materially affect the function of the process/method 400. In other examples, different components of an example device or system that implements the process/method 400 may perform functions at substantially the same time or in a specific sequence.

According to some examples, the process/method 400 includes at operation 402, receiving input data associated with one or more target assemblies. For example, the apparatus 200 may receive input data for a single target assembly or a plurality of target assemblies. The input data may comprise component list data for each of the one or more assemblies. Additionally, the input data may comprise ECAD and/or schematic for each of the one or more assemblies.

According to some examples, the process/method 400 includes at operation 404, generating, based on the input data and using one or more machine learning models, optimization data for at least one of the one or more target assemblies. For example, the apparatus 200 may generate based on the input data and using one or more machine learning models, optimization data for each of the one or more target assemblies in accordance with one or more of the optimization techniques described herein.

One or more of the optimization techniques may include analyzing and/or preprocessing the input data to generate data that is input into at least one of the one or more machine learning models to generate optimization data. Such analyzing and/or preprocess may include identifying one or more functional blocks associated with the plurality of assemblies, comparing the circuits and/or specification data for the assemblies to generate comparison data that comprising data that describes similarities and/or differences between the assembly circuits and data that describes similarities and/or differences between the assembly specifications.

In some embodiments, the apparatus 200 may perform one or more of component replacement-based optimization, functional block-based optimization, component standardization-based optimization, and/or modularization-based optimization as described above.

In some embodiments, component replacement-based optimization comprises, providing the input data (e.g., component list data, ECAD and/or schematic) for each of one or more target assemblies as input to a machine learning model configured to analyze the input data, and generate one or more recommended component list data for each target assembly. The recommend component list data for a given target assembly may comprise one or more recommended replacement components for one or more components of the target assembly. Such one or more components may be identified as a target component(s) for being replaced based on or more issues associated with the respective component.

In some embodiments, functional block-based optimization comprises identifying functional blocks associated with a plurality of target assemblies based on the input data (e.g., component list data, ECAD, and/or schematic) for the respective target assembly and using a machine learning model configured to receive the input data; analyze the input data; and output the functional block(s) associated with each assembly. Additionally, in some embodiments, other data, such as electrical connection data associated with each assembly, may be provided as input to the machine learning model and analyzed by the machine learning model along with the other input data to generate the functional blocks for the plurality of target assemblies.

In some embodiments, functional block-based optimization further comprises generating one or more functional block groups for the identified functional blocks, wherein each functional block group comprises one or more functional blocks (e.g., a subset of the identified functional blocks). In some embodiments, functional block-based optimization further comprises generating standard functional blocks (e.g., for replacing non-standard functional blocks) based on one or more optimization parameters, identifying assemblies from the plurality of assemblies having one or more non-standard functional blocks, and generating optimization data for the identified assemblies that include a non-standard functional block, wherein the optimization data comprises a corresponding standard functional block generated for the functional block group associated with the non-standard functional block for the assembly.

In some embodiments, component standardization-based optimization comprises identifying a plurality of disparate components associated with the plurality of assemblies. The plurality of disparate components may comprise electronic components associated with a particular category of components. For example, the plurality of disparate components may be associated with a microcontroller (MCU) component category, connector component category, passive component category, and/or the like. For example, the plurality of disparate components may comprise a plurality of disparate MCU components. As another example, the plurality of disparate components may comprise a plurality of disparate connectors. As yet another example, the plurality of components may comprise a plurality of disparate passive components. It would be appreciated that the plurality of disparate components may comprise other categories of components.

In some embodiments, component standardization-based optimization further comprises generating a plurality of component groups using a machine learning model configured to apply one or more clustering algorithms and clustering techniques to component data for the plurality of disparate components to generate the plurality of component groups. For example, component data for each component from the plurality of disparate components may be provided as input to the machine learning model. The machine learning model may apply one or more clustering algorithms and/or techniques to the input component data to generate a plurality of component groups, each comprising one or more components from the plurality of components that are deemed similar. In some embodiments, the component data may comprise one or more component characteristics such as type (e.g., family, architecture, FPU, instruction set, device core, and/or the like), peripherals (e.g., ADC, timers, DAC, PWM, interfaces, program I/O, and/or the like), package (e.g., package type, case, material, lead shape, and/or the like), performance (e.g., clock rate, CPU frequency, cache size, data bus, memory, RAM, and/or the like), and/or operating conditions (e.g., power dissipation, supply voltage, storage temperature, operating temperature).

In some embodiments, component standardization-based optimization further comprises generating a standard component for each component group to standardize the components across the plurality of assemblies. In some embodiments, generating a standard component for a component group may comprise identifying a component in the component group that satisfies one or more optimization parameters (e.g., as described above) as the standard component for the component group. In some embodiments, generating a component for a given component group may comprise identifying a component that is different from the components in the component group as the standard component based on the one or more optimization parameters.

In some embodiments, component standardization-based optimization further comprises identifying assemblies from the plurality of assemblies and/or related assets that include a non-standard component and generating optimization data for the identified assemblies and/or related asset, wherein the optimization data comprises a corresponding standard component generated for the component group associated with the non-standard component for the assembly or related asset. For example, the optimization data may comprise recommended component list data that includes recommend standard component for replacing non-standard components.

According to some examples, the process/method 400 includes at operation 406, generating design simulation result for a portion of the optimization data generated at operation 406 by performing on one or more design simulations (e.g.., physics-based design simulations, and/or the like), as described above. For example, the apparatus 200 may perform one or more physics-based design simulations for a portion of the recommended component list data in the optimization data generated at operation 404. The physics-based design simulations may comprise modeling an assembly design, based on the optimization data and using one or more modeling techniques, such as reduced order modeling; and performing one or more design simulations based on the updated assembly design model to validate the proposed changes to an assembly design. As described above, recommended component list data generated in accordance with the optimization techniques described herein may comprise proposed changes/modifications to an assembly design such proposed changes to one or more components of an assembly, proposed changes to functional blocks, and/or the like. In some embodiments, operation 406 is an optional step.

According, to some examples, the method includes at operation 408A, providing the optimization data for a target assembly to one or more client computing entities in response to a positive design simulation result (e.g., pass indication) for the target assembly. In some embodiments, the apparatus 200 may cause rendering of a user interface comprising the optimization data.

According, to some examples, the method includes at operation 408B, generating updated target data, in response to a negative design simulation result (e.g., fail indication) for a target assembly. For example, the apparatus 200 may cause the machine learning models 120 to regenerate optimization data for a target assembly.

According, to some examples, the method includes at operation 410, providing the design simulation result, as feedback, to the machine learning models(s) leveraged to generate optimization data, as described above. Such feedback may be provided to improve the accuracy of the machine learning model(s). Such machine learning model(s) may be configured to learn patterns based on the simulation results (as described above) (e.g., without explicitly running the simulations) and apply the learned patterns when generating optimization data for assemblies. In some embodiments, the machine learning model(s) leveraged to generate optimization data are trained based on historical data comprising previous optimization data and corresponding design simulation result.

### CONCLUSION

Although an example processing system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user’s client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. A computer-implemented method for assembly optimization and simulation, the computer-implemented method comprising:
identifying, by one or more processors, one or more assemblies, wherein each assembly of the one or more assemblies comprises a plurality of components;
generating, by the one or more processors, optimization data for the one or more assemblies based on input data associated with the one or more assemblies and using one or more machine learning models, wherein the optimization data comprises recommended component list data for each of the one or more assemblies;
generating, by the one or more processors, design simulation result prediction for the optimization data for the one or more assemblies; and
providing, by the one or more processors, the optimization data to one or more client computing entities in response to a positive design simulation result prediction.

2. The computer-implemented method of claim 1, wherein the input data comprises at least initial component list data for each of the one or more assemblies.

3. The computer-implemented method of claim 1, further comprising: generating design simulation result based on the optimization data for at least one of the one or more assemblies by performing one or more design simulations with respect to the optimization data.

4. The computer-implemented method of claim 3, further comprising:
providing the design simulation result as feedback to the one or more machine learning models, wherein the one or more machine learning models are configured to learn patterns of changes to assemblies that pass or fail the one or more design simulations.

5. The computer-implemented method of claim 3, wherein the one or more design simulations comprises one or more of signal integrity simulation, power integrity simulation, thermal analysis, or reliability analysis.

6. The computer-implemented method of claim 1, wherein the one or more machine learning models comprise a large language model.

7. The computer-implemented method of claim 1, wherein generating the optimization data further comprises performing one or more of component replacement-based optimization, component standardization-based optimization, or functional block-based optimization.

8. The computer-implemented method of claim 7, wherein the one or more assemblies comprise a plurality of assemblies, and wherein performing the functional block-based optimization comprises:
identifying a plurality of functional blocks associated with the plurality of assemblies based on (i) a schematic for each of the plurality of assemblies, (ii) specification for one or more operating parameters for each of the plurality of assemblies, and (iii) initial component list data for each of the plurality of assemblies;
generating one or more functional block groups based on data associated with the plurality of functional blocks and using a clustering machine learning model, wherein each functional block groups comprises one or more functional blocks from the plurality of functional blocks having similar characteristics; and
generating a standard functional block for each functional block group of the one or more functional block groups.

9. An apparatus for assembly optimization and simulation, the apparatus comprising at least one processor and at least one memory storing instructions that, when executed by the at least one processor, cause the apparatus to:
identify one or more assemblies, wherein each assembly of the one or more assemblies comprises a plurality of components;
generate optimization data for the one or more assemblies based on input data associated with the one or more assemblies and using one or more machine learning models, wherein the optimization data comprises recommended component list data for each of the one or more assemblies;
generate design simulation result prediction for the optimization data for the one or more assemblies; and
provide the optimization data to one or more client computing entities in response to a positive design simulation result prediction.

10. The apparatus of claim 9, wherein the input data comprises at least initial component list data for each of the one or more assemblies.

11. The apparatus of claim 9, wherein the apparatus is further caused to:
generate design simulation result based on the optimization data for at least one of the one or more assemblies by performing one or more design simulations with respect to the optimization data.

12. The apparatus of claim 11, wherein the apparatus is further caused to:
provide the design simulation result as feedback to the one or more machine learning models, wherein the one or more machine learning models are configured to learn patterns of changes to assemblies that pass or fail the one or more design simulations.

13. The apparatus of claim 11, wherein the one or more design simulations comprises one or more of signal integrity simulation, power integrity simulation, thermal analysis, or reliability analysis.

14. The apparatus of claim 9, wherein the one or more machine learning models comprise a large language model.

15. The apparatus of claim 9, wherein the apparatus generates the optimization data by performing one or more of component replacement-based optimization, component standardization-based optimization, or functional block-based optimization.

16. The apparatus of claim 15, wherein the one or more assemblies comprise a plurality of assemblies, and wherein performing the functional block-based optimization comprises:
identifying a plurality of functional blocks associated with the plurality of assemblies based on (i) a schematic for each of the plurality of assemblies, (ii) specification for one or more operating parameters for each of the plurality of assemblies, and (iii) initial component list data for each of the plurality of assemblies;
generating one or more functional block groups based on data associated with the plurality of functional blocks and using a clustering machine learning model, wherein each functional block groups comprises one or more functional blocks from the plurality of functional blocks having similar characteristics; and
generating a standard functional block for each functional block group of the one or more functional block groups.

17. At least one non-transitory computer-readable storage medium for assembly optimization and simulation, the at least one non-transitory computer-readable storage medium having computer coded instructions configured to, when executed by at least one processor:
identify one or more assemblies, wherein each assembly of the one or more assemblies comprises a plurality of components;
generate optimization data for the one or more assemblies based on input data associated with the one or more assemblies and using one or more machine learning models, wherein the optimization data comprises recommended component list data for each of the one or more assemblies;
generate design simulation result prediction for the optimization data for the one or more assemblies; and
provide the optimization data to one or more client computing entities in response to a positive design simulation result prediction.

18. The at least one non-transitory computer-readable storage medium of claim 17, wherein the input data comprises at least initial component list data for each of the one or more assemblies.

19. The at least one non-transitory computer-readable storage medium of claim 18, wherein the computer coded instructions further configured to, when executed by the at least one processor:
generate design simulation result based on the optimization data for at least one of the one or more assemblies by performing one or more design simulations with respect to the optimization data.

20. The at least one non-transitory computer-readable storage medium of claim 19, wherein the computer coded instructions further configured to, when executed by the at least one processor:
provide the design simulation result as feedback to the one or more machine learning models, wherein the one or more machine learning models are configured to learn patterns of changes to assemblies that pass or fail the one or more design simulations.
